(19) United States
(12) Patent Application Publication
(10) Pub. No.: US 2025/0255092 A1
(43) Pub. Date: Aug. 7, 2025

(54) ORGANIC ELECTROLUMINESCENT DEVICE AND DISPLAY APPARATUS

(71) Applicant: Kunshan New Flat Panel Display Technology Center Co., Ltd., Kunshan (CN)

(72) Inventors: Yu GAO, Kunshan (CN); Junzhe LIU, Kunshan (CN); Jingcheng XIA, Kunshan (CN); Tiantian LI, Kunshan (CN); Zhi HUANG, Kunshan (CN)

(73) Assignee: Kunshan New Flat Panel Display Technology Center Co., Ltd., Kunshan (CN)

(21) Appl. No.: 19/187,913

(22) Filed: Apr. 23, 2025

Related U.S. Application Data
(63) Continuation of application No. PCT/CN2023/085841, filed on Apr. 3, 2023.

(30) Foreign Application Priority Data
Nov. 11, 2022 (CN) 202211420815.6

(51) Int. Cl. H10K 50/135; H10K 85/30; H10K 85/40; H10K 85/60

(52) U.S. Cl. CPC H10K 50/135; H10K 85/324; H10K 85/342; H10K 85/40; H10K 85/622; H10K 85/623; H10K 85/626; H10K 85/633; H10K 85/654; H10K 85/656; H10K 85/6572; H10K 85/6574; H10K 85/6576; H10K 85/658

(57) ABSTRACT

An organic electroluminescent device, including at least one functional light-emitting layer. In a first target current density interval not greater than 0.01 mA/cm², an electron mobility V_{E} and a hole mobility V_{H} of the functional light-emitting layer satisfy the requirements of |V_{E}−V_{H}|>1×10⁻⁸ cm²/Vs. The organic electroluminescent device has a relatively low luminous efficiency under a low gray scale, thereby exhibiting relatively excellent display quality. Also disclosed is a display apparatus.

The present application is a continuation of International Application No. PCT/CN 2023/085841 filed on Apr. 3, 2023, which claims priority to Chinese patent application no. 202211420815.6, filed with the China National Intellectual Property Administration on Nov. 11, 2022 and entitled “ORGANIC ELECTROLUMINESCENT DEVICE AND DISPLAY APPARATUS”, both of which are hereby incorporated by reference in their entireties.

### FIELD

The present application relates to an organic electroluminescent device and display apparatus, which belongs to the field of organic electroluminescence.

### BACKGROUND

An organic electroluminescent device comprises a cathode, an anode, and a light-emitting layer between the cathode and the anode. By applying a voltage between the cathode and the anode, electrons from the cathode and holes from the anode will be recombined in the light-emitting layer to generate excitons, and light is emitted accompanied by the radiation relaxation of the excitons toward the ground state.

Currently, the luminous color of an organic electroluminescent device is determined by the red, green, and blue light-emitting materials in a light-emitting layer, and various luminous colors can be achieved by adjusting the emission ratios of the three light-emitting materials. Based on the requirements of the luminous efficiency and service life of an organic electroluminescent device, the red and green light-emitting materials now are mainly high-efficiency phosphorescent light-emitting materials, and the blue light-emitting material is generally a long-lifespan fluorescent light-emitting material.

However, this combination of materials often causes the red and green light to have high luminous efficiency even under a low gray scale, resulting in a problem of difficult control of the emission ratios of red and green light. For example, it is difficult to shut off red and green light, or red and green light causes crosstalk with blue light, thus eventually leading to extremely poor display under a low gray scale. Excellent display quality under a low gray scale is one of the core criteria for evaluating the performance of an organic electroluminescent device. Therefore, how to make an electroluminescent device have excellent display quality under a low gray scale is an urgent problem to be addressed in the art.

### SUMMARY

The present application provides an organic electroluminescent device, which exhibits relatively excellent display quality since problems such as light crosstalk under a low gray scale are significantly suppressed.

The present application provides a display apparatus, which has excellent display quality.

The present application provides an organic electroluminescent device, comprising at least one functional light-emitting layer,

wherein in a first target current density interval not greater than 0.01 mA/cm², an electron mobility V_{E} and a hole mobility V_{H} of the at least one functional light-emitting layer satisfy the requirements of Formula 1:

$$\vert {V}_{E} - {V}_{H} \vert > {1}^{*} 1 {0}^{- 8} c {m}^{2} / Vs . \qquad Formula 1$$

In the organic electroluminescent device as described above, the functional light-emitting layer is a red light-emitting layer or a green light-emitting layer.

In the organic electroluminescent device as described above, the at least one functional light-emitting layer comprises a plurality of functional light-emitting layers, the functional light-emitting layers comprise a red light-emitting layer and a green light-emitting layer.

In the organic electroluminescent device as described above, within the first target current density interval, the electron mobility V_{E} and the hole mobility V_{H} of the functional light-emitting layer satisfy the requirements of Formula 2:

$$\vert {V}_{E} - {V}_{H} \vert > {2}^{*} 1 {0}^{- 8} c {m}^{2} / Vs . \qquad Formula 2$$

In the organic electroluminescent device as described above, within a target current subinterval of greater than 0.01 mA/cm² and less than or equal to 5 mA/cm², the electron mobility V_{E} and the hole mobility V_{H} of the functional layer satisfy the requirements of Formula 3:

$$\vert {V}_{E} - {V}_{H} \vert ⩽ {1}^{*} 1 {0}^{- 8} c {m}^{2} / Vs . \qquad Formula 3$$

In the organic electroluminescent device as described above, within a target current subinterval of greater than 5 mA/cm², the electron mobility V_{E} and the hole mobility V_{H} of the functional layer satisfy the requirements of Formula 4:

$$\vert {V}_{E} - {V}_{H} \vert ⩽ {3.5}^{*} 1 {0}^{- 6} c {m}^{2} / Vs . \qquad Formula 4$$

In the organic electroluminescent device as described above, within a second target current density interval of greater than 0.01 mA/cm² and less than or equal to 10 mA/cm², the electron mobility V_{E1} and the hole mobility V_{H1} of the functional light-emitting layer at a first current density and the electron mobility V_{E2} and the hole mobility V_{H2} of the functional light-emitting layer at a second current density satisfy the requirements of Formula 5:

$$0 < \vert {V}_{E 2} - {V}_{H 2} \vert < \vert {V}_{E 1} - {V}_{H 1} \vert \qquad Formula 5$$

wherein the first current density is less than the second current density.

In the organic electroluminescent device as described above, within a second target current density interval of greater than 0.01 mA/cm² and less than or equal to 10 mA/cm², the electron mobility V_{E3} and the hole mobility V_{H3} of the functional light-emitting layer at a third current density satisfy the requirements of Formula 6:

$$\vert {V}_{E 3} - {V}_{H 3} \vert = 0. \qquad Formula 6$$

The present application further provides a display apparatus, comprising any one of the organic electroluminescent devices described above.

The organic electroluminescent device of the present application has weakened luminous efficiency under a low gray scale because there is a significant difference between hole transport and electron transport properties of the functional light-emitting layer at a low current density. Thus, it is easier to shut off the functional light-emitting layer under a low gray scale; meanwhile, the difference in terms of turn-on voltage between the functional light-emitting layer and a light-emitting layer susceptible to crosstalk (e.g., a blue light-emitting layer) is reduced, thus avoiding the problem of luminescence crosstalk caused by the improper luminescence of the crosstalk-prone light-emitting layer to the light-emitting layer susceptible to crosstalk and improving the display quality.

### BRIEF DESCRIPTION OF THE DRAWINGS

FIG. 1 shows the photoluminescence spectra of the organic electroluminescent devices of Example 1, Example 9, and Comparative example 2 of the present application.

### DETAILED DESCRIPTION OF THE EMBODIMENTS

To make the embodiments of the present application clearer, the embodiments in the examples of the present application will be described clearly and completely below with reference to the examples of the present application. The examples described are part of, rather than all of, the examples of the present application.

One embodiment of the present application provides an organic electroluminescent device, which comprises a light-emitting layer and an anode and a cathode provided, respectively, on both sides of the light-emitting layer, wherein the light-emitting layer comprises at least one functional light-emitting layer.

Specifically, the cathode and the anode may be made of materials commonly used in the art. For example, the material of the anode may be a transparent conductive oxide material such as indium tin oxide (ITO), indium zinc oxide (IZO), tin dioxide (SnO₂) and zinc oxide (ZnO), and any combination thereof; and the cathode may be made of a metal or alloy such as magnesium (Mg), silver (Ag), aluminum (Al), aluminum-lithium (Al—Li), calcium (Ca), magnesium-indium (Mg—In) and magnesium-silver (Mg—Ag), and any combination thereof.

The functional light-emitting layer is described in detail below.

In a first target current density interval not greater than 0.01 mA/cm², an electron mobility V_{E} and a hole mobility V_{H} of the functional light-emitting layer of the present application satisfy the requirements of Formula 1:

$$\vert {V}_{E} - {V}_{H} \vert > 1 * {10}^{- 8} {cm}^{2} / V s . \qquad Formula 1$$

That is, the functional light-emitting layer in the organic electroluminescent device of the present application has a significant difference between electron mobility and hole mobility in the first target current density interval. Specifically, the difference between electron mobility and hole mobility is not less than 1*10⁻⁸ cm²/Vs. Therefore, in the first target current interval, the difference between the electron mobility and the hole mobility of the functional light-emitting layer achieves the adjustment of the electron-hole recombination rate of the functional light-emitting layer and eventually enables the functional light-emitting layer to exhibit lower luminous efficiency. A decrease in the luminous efficiency better facilitates the shutoff of the functional light-emitting layer, avoiding the problem of unsatisfactory display of a luminous color caused by uncontrollable shutoff of a crosstalk-prone layer. Moreover, a decrease in the luminous efficiency of the functional light-emitting layer is favorable for lowering the turn-on voltage of the functional light-emitting layer. This results in a narrowed difference in terms of turn-on voltage between the functional light-emitting layer and a light-emitting layer susceptible to crosstalk (e.g., a blue light-emitting layer) and ultimately suppresses, to a great extent, the existing problem of the crosstalk of the crosstalk-prone light-emitting layer to the light-emitting layer susceptible to crosstalk. Therefore, the organic electroluminescent device of the present application exhibits relatively excellent display quality under a low gray scale (at a relatively low current density).

It can be understood that when the crosstalk-prone light-emitting layers in an organic electroluminescent device all are functional light-emitting layers, it is more favorable to reduce the adverse effects of the uncontrollable shutoff of the crosstalk-prone light-emitting layers and the luminescence crosstalk on the display quality of the organic electroluminescent device.

The method for acquiring electron mobility and hole mobility in the present application is as follows.

An electron-only device and a hole-only device are made by using a light-emitting layer of the organic electroluminescent device, and the electron-only device and the hole-only device are used as detection objects to respectively calculate an electron mobility and a hole mobility, with the composition of the light-emitting layers of the electron-only device and the hole-only device being the same as that of the light-emitting layer of the organic electroluminescent device. Specifically, the electron-only device comprises, in sequence, an anode, a hole blocking layer, a light-emitting layer, an electron transport layer, an electron injection layer, and a cathode; and the hole-only device comprises, in sequence, an anode, a hole injection layer, a hole transport layer, a light-emitting layer, an electron blocking layer, and a cathode. It should be noted that the materials of the functional layers, other than the light-emitting layer, of the electron-only device and the hole-only device may be the same or different from the materials of the corresponding functional layers of the organic electroluminescent device.

When measuring the electron mobility, the resulting electron-only device is tested using an IVL test machine with a test range starting from 0 V and ending at a current density of 50 mA/cm² to obtain the current density data of the electron-only device as the voltage changes. The mobility is then calculated according to the following equation.

$${j}_{SCLC} = \frac{9}{8} {εε}_{0} μ \frac{{V}^{2}}{{d}^{3}} \qquad Equation A$$

In Equation A, J is current density, ε₀ is vacuum permittivity, ε is relative permittivity, μ is mobility, V is voltage, d is the thickness of a thin film (a functional layer after removing the cathode and anode in the device).

Similarly, when measuring the hole mobility, the test above is performed using the hole-only device as a detection object, and no more detailed description is to be given here.

It should be noted that the units of the electron mobility and the hole mobility in the present application are both cm²/Vs.

Since a red light-emitting layer and/or green light-emitting layer easily cause crosstalk with a blue light-emitting layer, in a specific embodiment, the functional light-emitting layer comprises at least one red light-emitting layer and green light-emitting layer, which helps to reduce the crosstalk of the red light-emitting layer and/or green light-emitting layer as a crosstalk-prone light-emitting layer to a light-emitting layer susceptible to crosstalk (the blue light-emitting layer), and improves the display quality of the organic electroluminescent device under a low, gray scale.

Further, when the electron mobility V_{E} and the hole mobility V_{H} in the first target current density interval satisfy the requirements of Formula 2, there is a greater difference in the transport and injection capabilities between the holes and electrons of the functional light-emitting layer, which is thus conducive to further mitigating adverse effects of red and green light-emitting layers on the display quality, making the organic electroluminescent device achieve a more balanced and ideal color display.

$$\vert {V}_{E} - {V}_{H} \vert > 2 * {10}^{- 8} {cm}^{2} / V s . \qquad Formula 2$$

In the organic electroluminescent device of the present application, the functional light-emitting layer having lower luminous efficiency at a low current density weakens the adverse effects of the red and green light-emitting layers on the display quality of the organic electroluminescent device under a low gray scale and enables the organic electroluminescent device to exhibit a better color display effect under a low gray scale by alleviating the problems of difficult shutoff of the red and green light-emitting layers and excessively high turn-on voltage.

Further, on the basis of the demands of the organic electroluminescent device for high luminous efficiency and low roll-off under a high gray scale, in a target current subinterval of greater than 0.01 mA/cm² and less than or equal to 5 mA/cm², an electron mobility V_{E} and a hole mobility V_{H} of the functional layer satisfy the requirements of Formula 3:

$$\vert {V}_{E} - {V}_{H} \vert ⩽ 1 * {10}^{- 8} {cm}^{2} / V s . \qquad Formula 3$$

It is clear that in the target current subinterval of greater than 0.01 mA/cm² but smaller than or equal to 5 mA/cm², the difference between the electron mobility and the hole mobility of the functional light-emitting layer satisfying Formula 3 is small. Therefore, under a high gray scale (at a relatively high current density), the difference between the electron injection and transport capability and the hole injection and transport capability of the functional light-emitting layer is small; thus, in virtue of a relatively high electron-hole recombination rate, the system can have more excitons capable of realizing energy level transitions and energy transfer, which is beneficial for improving the luminous efficiency and reducing the efficiency roll-off of the organic electroluminescent device under a high gray scale.

In addition, by limiting the difference between the electron mobility and the hole mobility of the functional layer at a higher gray scale, the demand of the organic electromechanical device for high luminous efficiency under a high gray scale can also be achieved. Specifically, in a target current subinterval of greater than 5 mA/cm², the electron mobility V_{E} and hole mobility V_{H} of the functional layer satisfy the requirements of Formula 4:

$$\vert {V}_{E} - {V}_{H} \vert ⩽ 3.5 * {10}^{- 6} {cm}^{2} / V s . \qquad Formula 4$$

Under high-gray-scale conditions in a range of greater than 5 mA/cm², the difference between the electron mobility and the hole mobility of the functional layer satisfying Formula 4 is relatively small, the electron transport and injection capacity and the hole transport and injection capacity of the functional light-emitting layer are relatively balanced, and the organic electroluminescent device exhibits satisfactory luminous efficiency by maintaining a high electron-hole recombination rate.

Still further, in a specific embodiment, in a second target current density interval of greater than 0.01 mA/cm2 and less than or equal to 10 mA/cm², the electron mobility V_{E1} and the hole mobility V_{H1} of the functional light-emitting layer at a first current density and the electron mobility V_{E2} and the hole mobility V_{H2} of the functional light-emitting layer at a second current density satisfy the requirements of Formula 5:

$$0 < \vert {V}_{E 2} < {V}_{H 2} \vert < \vert {V}_{E 1} - {V}_{H 1} \vert \qquad Formula 5$$

wherein the first current density is less than the second current density.

That is, in the second target current density interval, with the gradual increase of the current density, the difference between the electron mobility and the hole mobility of the functional light-emitting layer gradually decreases. The increasingly decreased difference indicates that electrons from the cathode and holes from the anode can enter the functional light-emitting layer in such a way that the capacity and number of the two tend to be more balanced and equal to realize one-to-one recombination and generate excitons, such that the defect of imbalanced carriers in the functional light-emitting layer due to imbalanced electron and hole transport capabilities, and by increasing the utilization rate of carriers, the organic electroluminescent device has better luminous efficiency at gradually increased current densities. In the present application, the specific values of the first current density and the second current density are not limited, as long as they are within the second target current density interval.

In another specific embodiment, in the second target current density interval of greater than 0.01 mA/cm² and less than or equal to 10 mA/cm², the electron mobility V_{E3} and the hole mobility V_{H3} of the functional light-emitting layer at a third current density satisfy the requirements of Formula 6:

$$\vert {V}_{E 3} - {V}_{H 3} \vert = 0. \qquad Formula 6$$

In this case, the electron transport and injection capability and the hole transport and injection capability are equivalent and balanced, and electrons and holes are distributed in the functional light-emitting layer in an equal and balanced manner, and undergo one-to-one recombination to generate excitons, thereby further improving the luminous efficiency of the organic electroluminescent device under a high gray scale. The third current density is not unique; that is, in the second target current density interval, there is a plurality of different third current densities where the electron mobility and the hole mobility of the functional layer are equal.

It should be noted that the organic electroluminescent device of the present application can meet the requirements of both Formula 5 and Formula 6 in the second target current density interval of greater than 0.01 mA/cm² and less than or equal to 10 mA/cm².

In the present application, by making the difference between the electron mobility and the hole mobility of the functional light-emitting layer different at different current densities, not only are the problems of the red and green light-emitting layers of the organic electroluminescent device difficult to shut off and causing crosstalk with the blue light-emitting layer under a low gray scale due to abnormal display solved, but the luminous efficiency of the organic electroluminescent device under a high gray scale is also improved, thereby making the organic electroluminescent device have excellent display quality.

The inventors have found that by controlling the combination manner of the composition of the functional light-emitting layer, it is possible to control the differences between the electron mobility and the hole mobility of the functional light-emitting layer at different current densities. Certainly, the present application does not limit the specific composition of the functional light-emitting layer, and any functional light-emitting layer that satisfies the aforementioned limitations falls within the scope of protection of the present application.

Generally, a functional light-emitting layer comprises a host material and a guest material, and in specific applications, the matching host materials and guest materials can be selected on the basis of the demands for the difference relationship between different electron mobilities and hole mobilities of the functional light-emitting layer at different current densities.

In an embodiment, the host material comprises a bipolar material, or the host material comprises at least one of a mixture of an electron-donor material and an electron-acceptor material, a mixture of a bipolar material and an electron-donor material, and a mixture of a bipolar material and an electron-acceptor material.

The guest material is a phosphorescent dye or a fluorescent dye.

The bipolar material above refers to a compound having both an electron-donating group and an electron-accepting group.

The mixture above refers to the fact that the host material comprises at least one of a mixture of a hole-type material (an electron-donor material) and an electron-type material (an electron-acceptor material), and a mixture of a bipolar material and a hole-type material or an electron-type material. Generally, the mass ratio of the two materials in the mixture is (1-9):(9-1), further (3-7):(7-3), and still further (4-6):(6-4). In one embodiment, in a mixture of an electron-donor material and an electron-acceptor material, the mass ratio of the electron-donor material to the electron-acceptor material is (1-9):(9-1). In a mixture of an electron-donor material and an electron-acceptor material, the mass ratio of the electron-donor material to the electron-acceptor material is (3-7):(7-3). In a mixture of an electron-donor material and an electron-acceptor material, the mass ratio of the electron-donor material to the electron-acceptor material is (4-6): (6-4). In a mixture of a bipolar material and an electron-donor material, the mass ratio of the bipolar material to the electron-donor material is (1-9):(9-1). In a mixture of a bipolar material and an electron-donor material, the mass ratio of the bipolar material to the electron-donor material is (3-7):(7-3). In a mixture of a bipolar material and an electron-donor material, the mass ratio of the bipolar material to the electron-donor material is (4-6):(6-4). In a mixture of a bipolar material and an electron-acceptor material, the mass ratio of the bipolar material to the electron-acceptor material is (1-9):(9-1). In a mixture of a bipolar material and an electron-acceptor material, the mass ratio of the bipolar material to the electron-acceptor material is (3-7):(7-3). In a mixture of a bipolar material and an electron-acceptor material, the mass ratio of the bipolar material to the electron-acceptor material is (4-6):(6-4).

Still further, The host material is a mixture of a bipolar material and an electron-donor material, and the host material is a mixture of a bipolar material and an electron-donor material with a mass ratio of 1:1.

The electron-donor material is a compound that contains at least one electron-donating group selected from carbazolyl, arylamino, silyl, fluorenyl, dibenzothienyl, and dibenzofuranylaryl and has a hole transport property.

Specifically, the electron-donor material may be selected from, but is not limited to, a compound represented by one of the following structures:

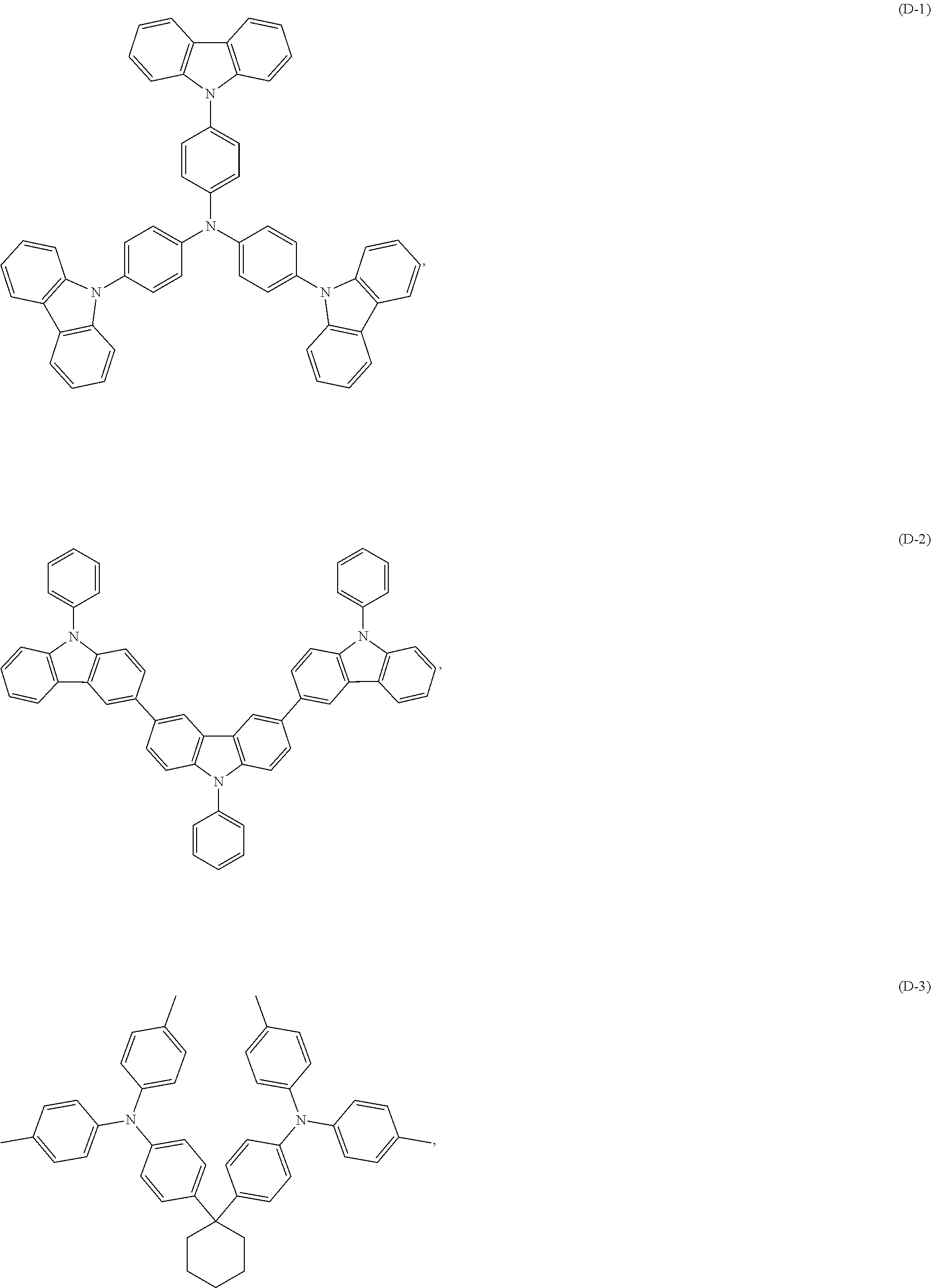

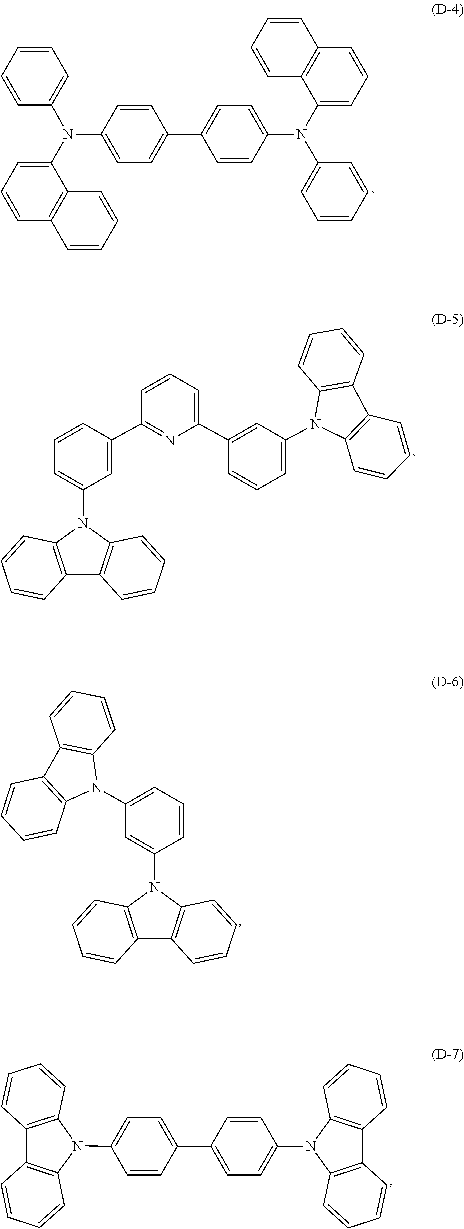 [SMILES: c1ccc(N(c2ccc(-c3ccc(N(c4ccccc4)c4cccc5ccccc45)cc3)cc2)c2cccc3ccccc23)cc1 ; c1cc(-c2cccc(-c3cccc(-n4c5ccccc5c5ccccc54)c3)n2)cc(-n2c3ccccc3c3ccccc32)c1 ; c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1]

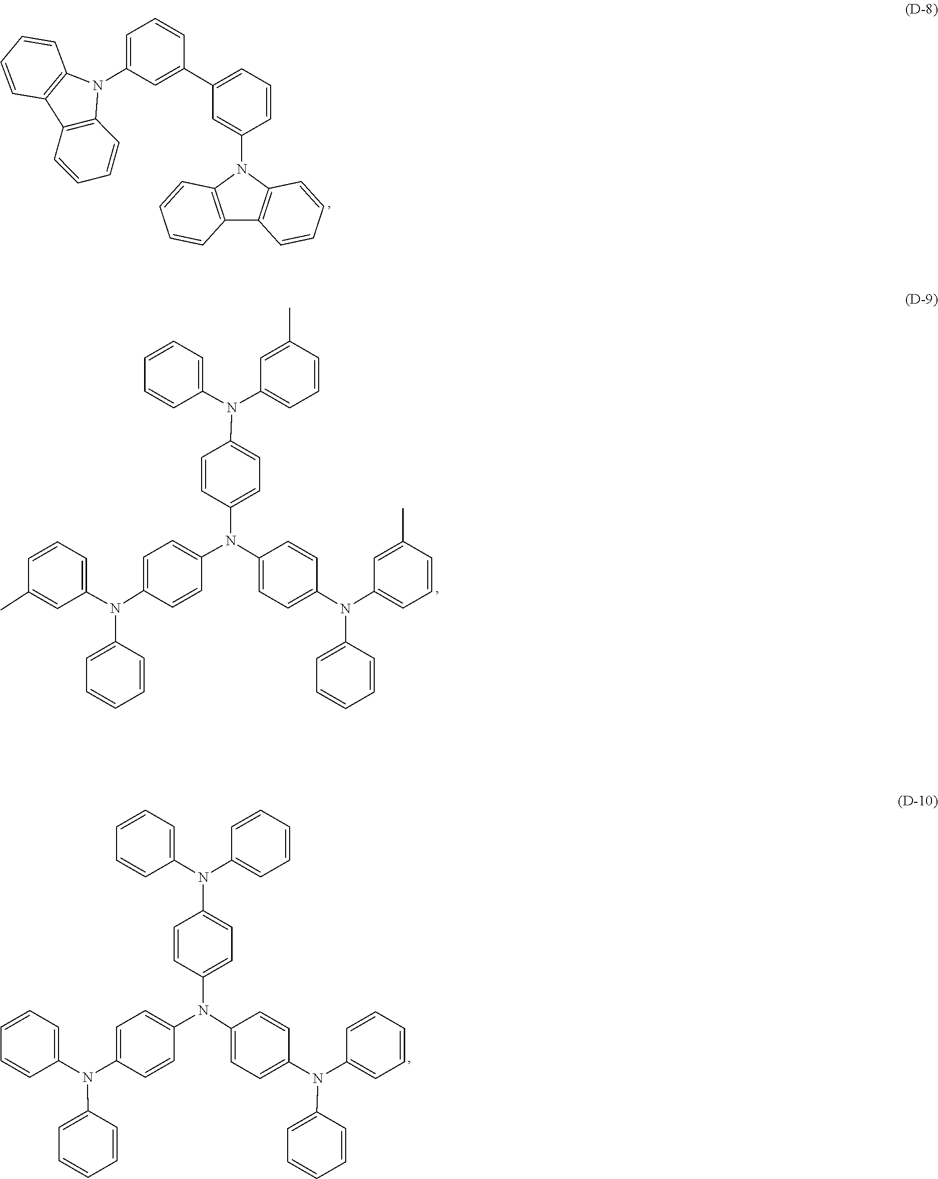 [SMILES: c1cc(-c2cccc(-n3c4ccccc4c4ccccc43)c2)cc(-n2c3ccccc3c3ccccc32)c1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccccc2)c2ccc(N(c3ccc(N(c4ccccc4)c4ccccc4)cc3)c3ccc(N(c4ccccc4)c4ccccc4)cc3)cc2)cc1]

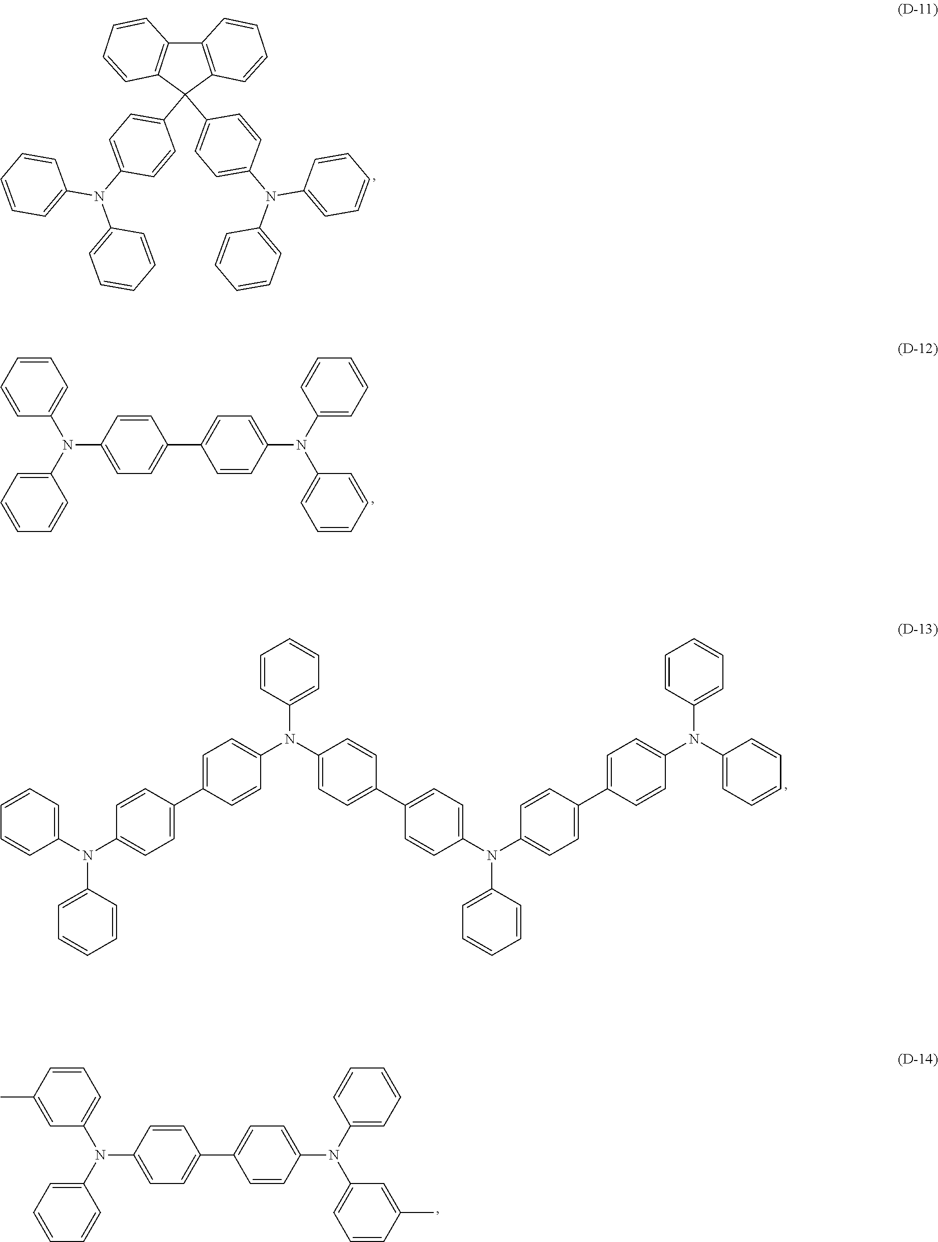

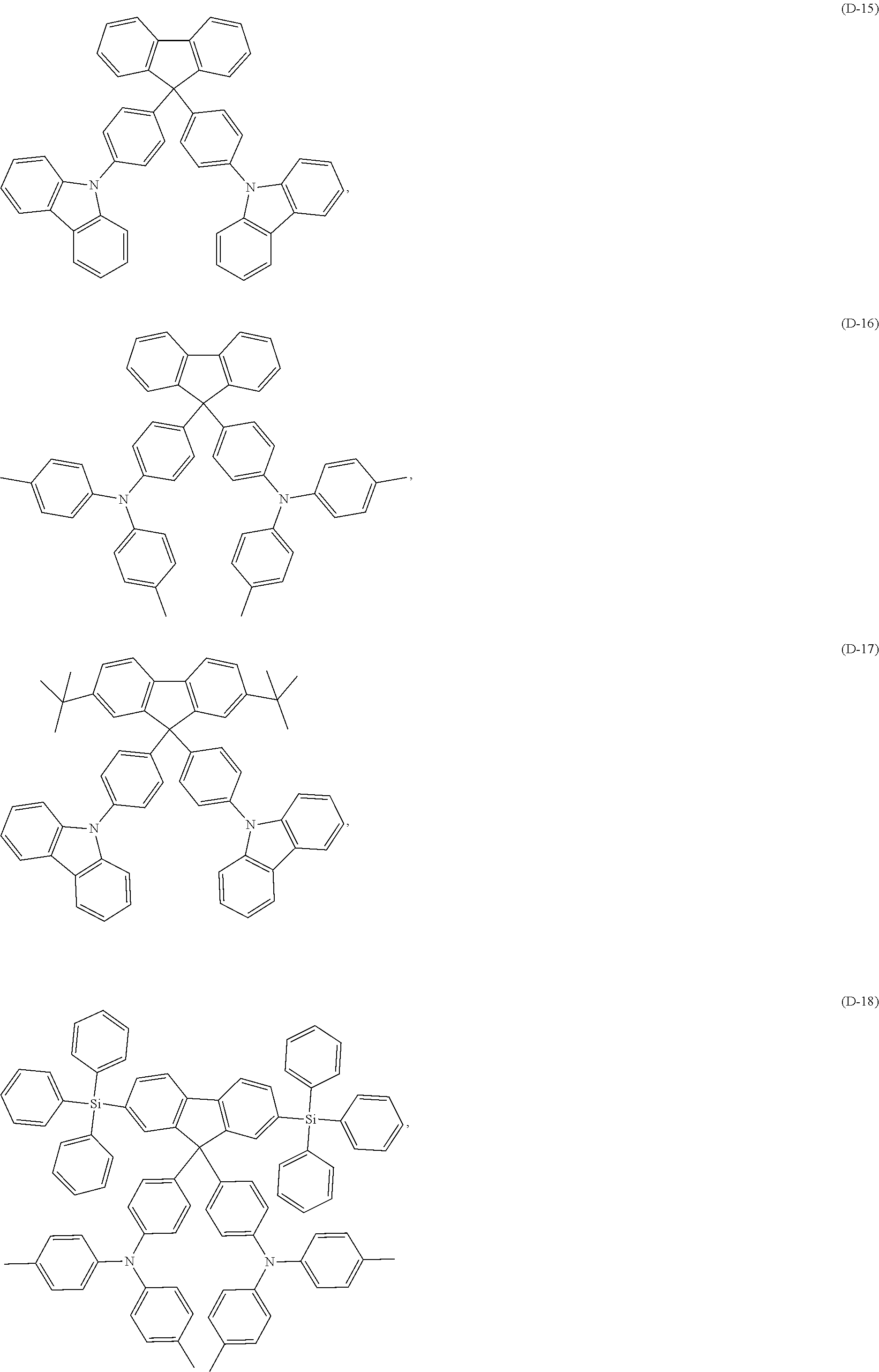

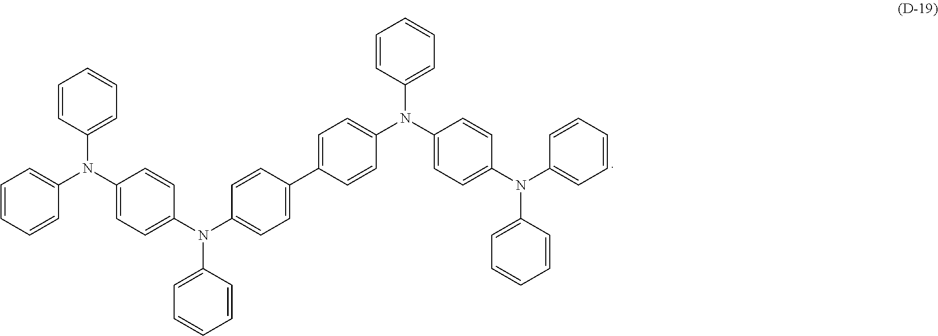 [SMILES: c1ccc(N(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1]

The electron-acceptor material is a compound that contains at least one electron-accepting group selected from pyridyl, pyrimidinyl, triazinyl, imidazolyl, o-phenanthrolinyl, sulfonyl, heptazinyl, oxadiazolyl, cyano, and diphenylphosphoryl and has an electron transport property.

Specifically, the electron-acceptor material may be selected from, but is not limited to, a compound represented by one of the following structures:

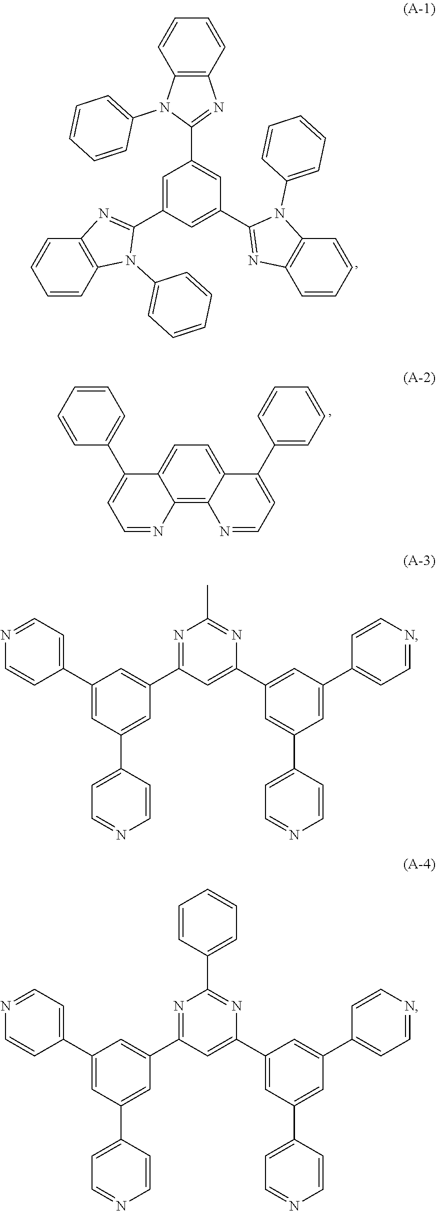 [SMILES: c1ccc(-n2c(-c3cc(-c4nc5ccccc5n4-c4ccccc4)cc(-c4nc5ccccc5n4-c4ccccc4)c3)nc3ccccc32)cc1 ; c1ccc(-c2ccnc3c2ccc2c(-c4ccccc4)ccnc23)cc1 ; Cc1nc(-c2cc(-c3ccncc3)cc(-c3ccncc3)c2)cc(-c2cc(-c3ccncc3)cc(-c3ccncc3)c2)n1 ; c1ccc(-c2nc(-c3cc(-c4ccncc4)cc(-c4ccncc4)c3)cc(-c3cc(-c4ccncc4)cc(-c4ccncc4)c3)n2)cc1]

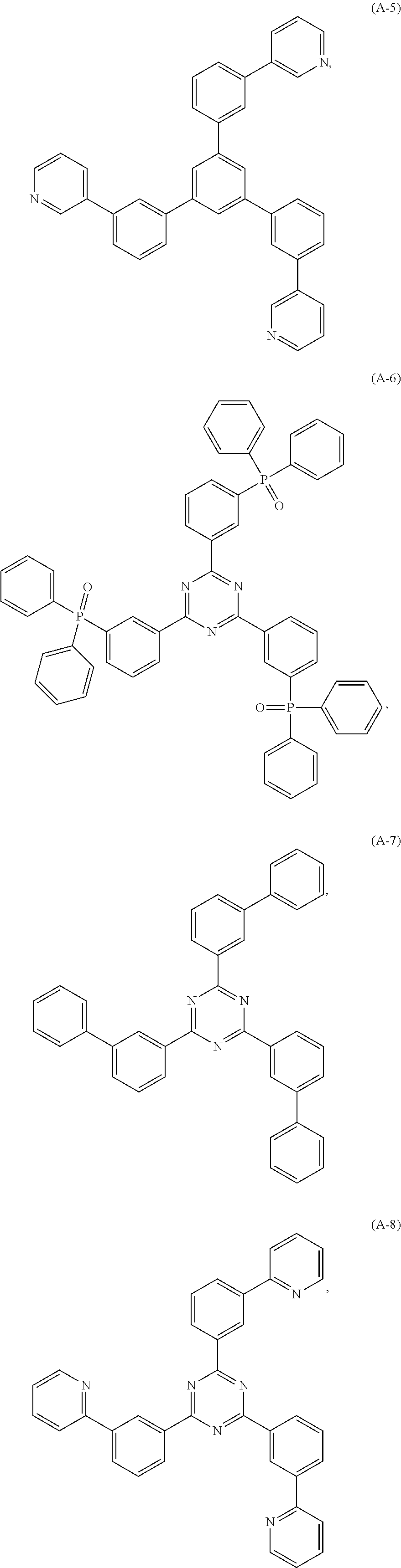 [SMILES: c1cncc(-c2cccc(-c3cc(-c4cccc(-c5cccnc5)c4)cc(-c4cccc(-c5cccnc5)c4)c3)c2)c1 ; O=P(c1ccccc1)(c1ccccc1)c1cccc(-c2nc(-c3cccc(P(=O)(c4ccccc4)c4ccccc4)c3)nc(-c3cccc(P(=O)(c4ccccc4)c4ccccc4)c3)n2)c1 ; c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4cccc(-c5ccccn5)c4)nc(-c4cccc(-c5ccccn5)c4)n3)c2)nc1]

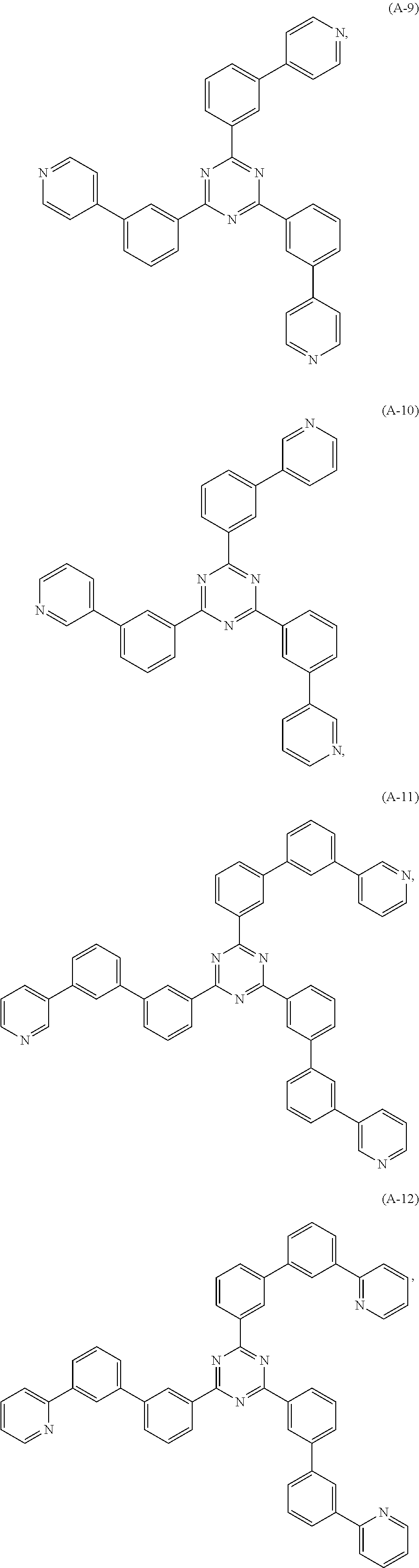 [SMILES: c1cc(-c2ccncc2)cc(-c2nc(-c3cccc(-c4ccncc4)c3)nc(-c3cccc(-c4ccncc4)c3)n2)c1 ; c1cncc(-c2cccc(-c3nc(-c4cccc(-c5cccnc5)c4)nc(-c4cccc(-c5cccnc5)c4)n3)c2)c1 ; c1cncc(-c2cccc(-c3cccc(-c4nc(-c5cccc(-c6cccc(-c7cccnc7)c6)c5)nc(-c5cccc(-c6cccc(-c7cccnc7)c6)c5)n4)c3)c2)c1 ; c1ccc(-c2cccc(-c3cccc(-c4nc(-c5cccc(-c6cccc(-c7ccccn7)c6)c5)nc(-c5cccc(-c6cccc(-c7ccccn7)c6)c5)n4)c3)c2)nc1]

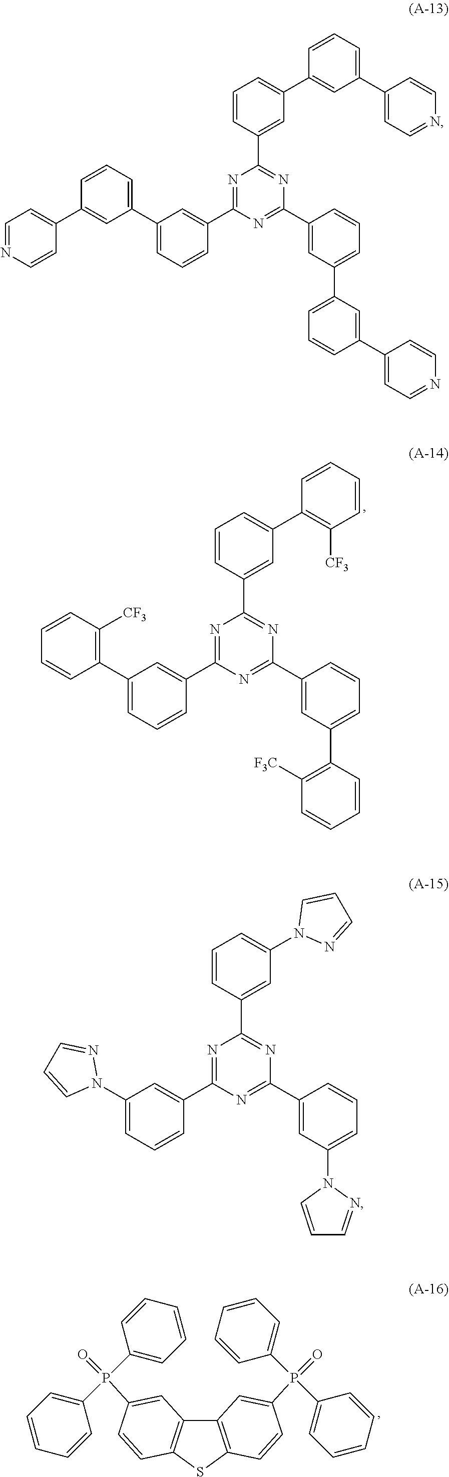 [SMILES: c1cc(-c2ccncc2)cc(-c2cccc(-c3nc(-c4cccc(-c5cccc(-c6ccncc6)c5)c4)nc(-c4cccc(-c5cccc(-c6ccncc6)c5)c4)n3)c2)c1 ; FC(F)(F)c1ccccc1-c1cccc(-c2nc(-c3cccc(-c4ccccc4C(F)(F)F)c3)nc(-c3cccc(-c4ccccc4C(F)(F)F)c3)n2)c1 ; c1cc(-c2nc(-c3cccc(-n4cccn4)c3)nc(-c3cccc(-n4cccn4)c3)n2)cc(-n2cccn2)c1 ; O=P(c1ccccc1)(c1ccccc1)c1ccc2sc3ccc(P(=O)(c4ccccc4)c4ccccc4)cc3c2c1]

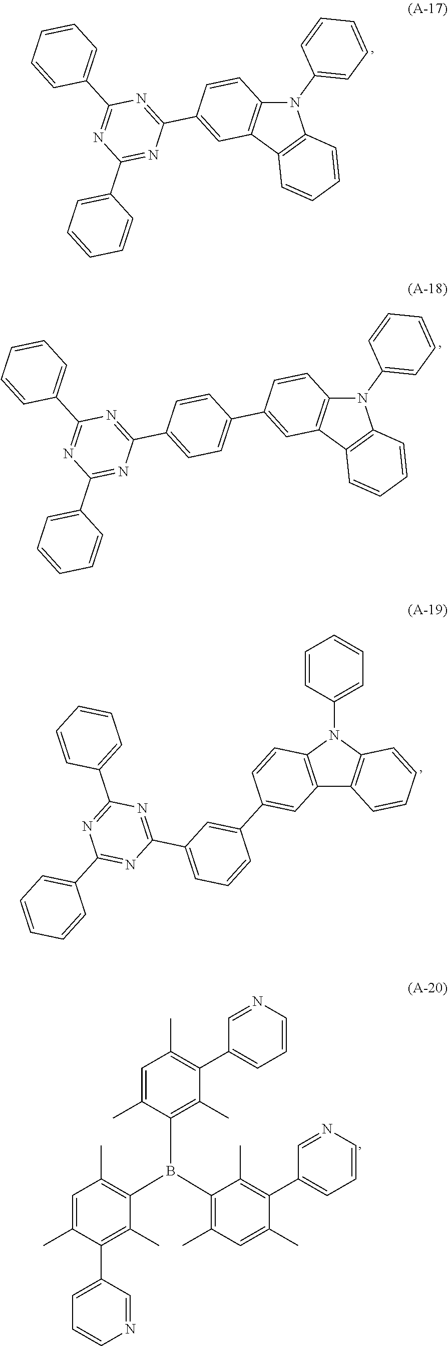 [SMILES: c1ccc(-c2nc(-c3ccccc3)nc(-c3ccc4c(c3)c3ccccc3n4-c3ccccc3)n2)cc1 ; c1ccc(-c2nc(-c3ccccc3)nc(-c3ccc(-c4ccc5c(c4)c4ccccc4n5-c4ccccc4)cc3)n2)cc1 ; c1ccc(-c2nc(-c3ccccc3)nc(-c3cccc(-c4ccc5c(c4)c4ccccc4n5-c4ccccc4)c3)n2)cc1 ; Cc1cc(C)c(-c2cccnc2)c(C)c1B(c1c(C)cc(C)c(-c2cccnc2)c1C)c1c(C)cc(C)c(-c2cccnc2)c1C]

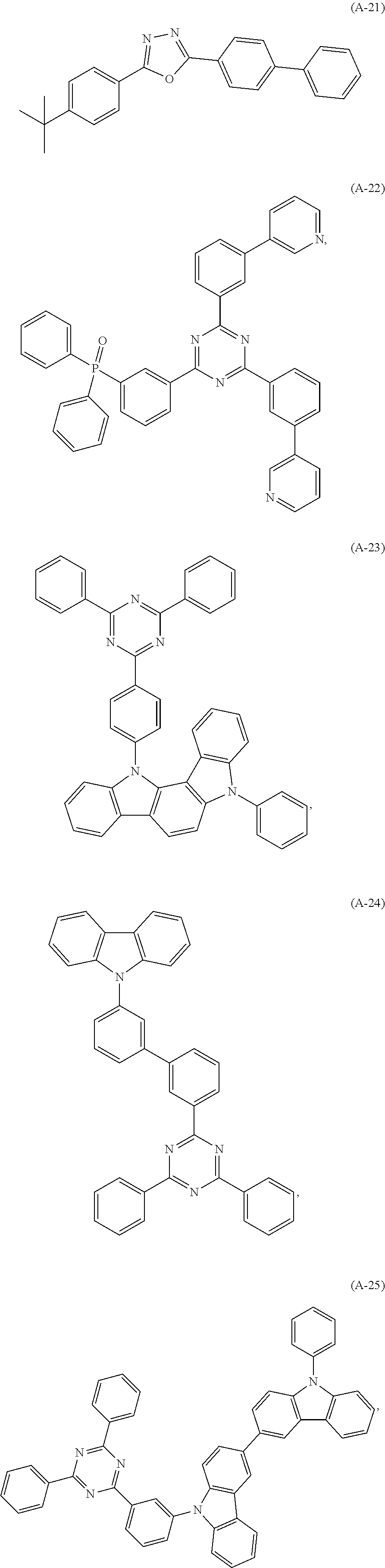 [SMILES: CC(C)(C)c1ccc(-c2nnc(-c3ccc(-c4ccccc4)cc3)o2)cc1 ; O=P(c1ccccc1)(c1ccccc1)c1cccc(-c2nc(-c3cccc(-c4cccnc4)c3)nc(-c3cccc(-c4cccnc4)c3)n2)c1 ; c1ccc(-c2nc(-c3ccccc3)nc(-c3ccc(-n4c5ccccc5c5ccc6c(c7ccccc7n6-c6ccccc6)c54)cc3)n2)cc1 ; c1ccc(-c2nc(-c3ccccc3)nc(-c3cccc(-c4cccc(-n5c6ccccc6c6ccccc65)c4)c3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

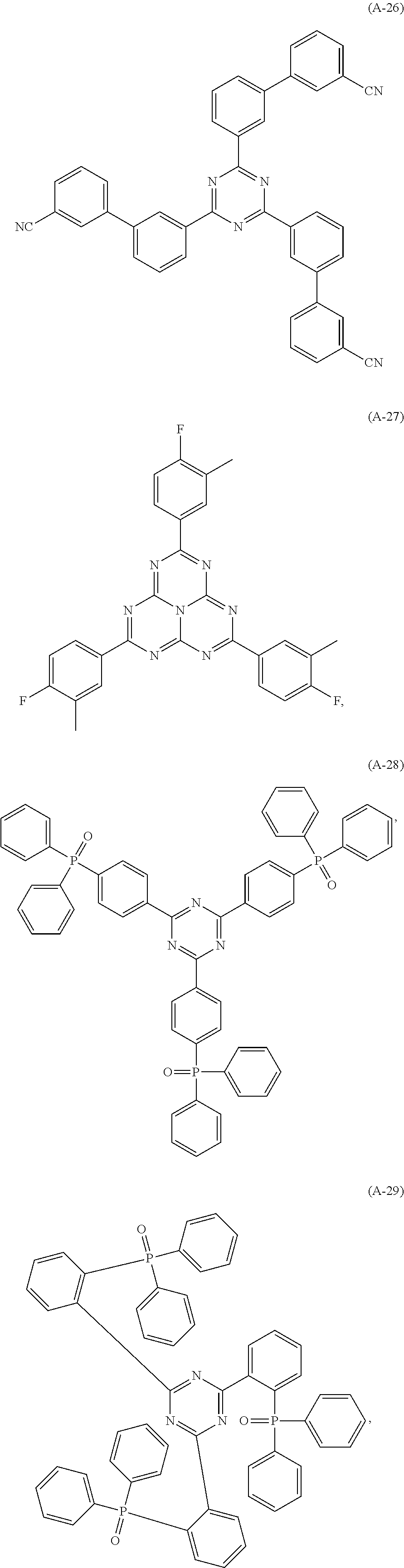 [SMILES: N#Cc1cccc(-c2cccc(-c3nc(-c4cccc(-c5cccc(C#N)c5)c4)nc(-c4cccc(-c5cccc(C#N)c5)c4)n3)c2)c1 ; Cc1cc(C2=NC3=NC(c4ccc(F)c(C)c4)=NC4=NC(c5ccc(F)c(C)c5)=NC(=N2)N34)ccc1F ; O=P(c1ccccc1)(c1ccccc1)c1ccc(-c2nc(-c3ccc(P(=O)(c4ccccc4)c4ccccc4)cc3)nc(-c3ccc(P(=O)(c4ccccc4)c4ccccc4)cc3)n2)cc1 ; O=P(c1ccccc1)(c1ccccc1)c1ccccc1-c1nc(-c2ccccc2P(=O)(c2ccccc2)c2ccccc2)nc(-c2ccccc2P(=O)(c2ccccc2)c2ccccc2)n1]

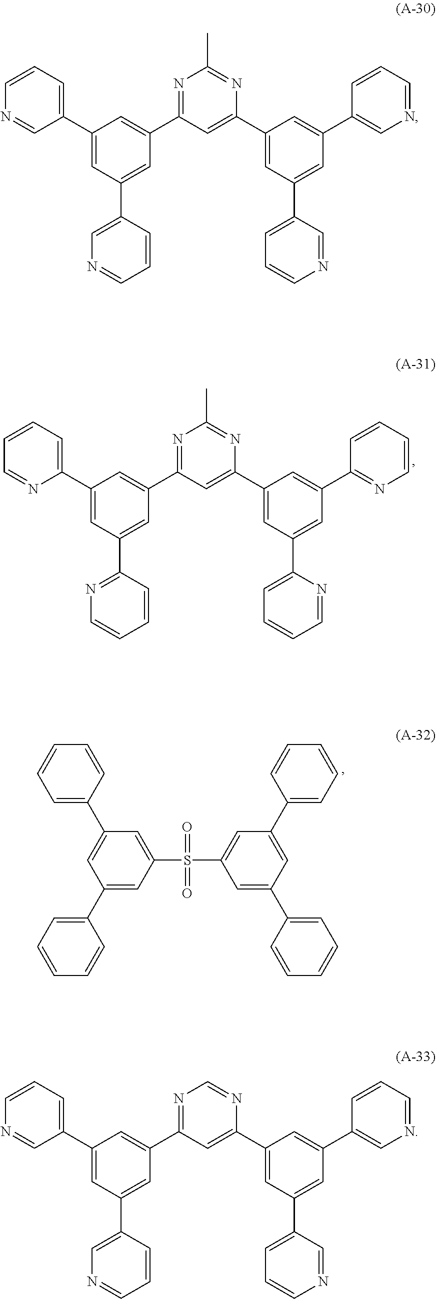 [SMILES: Cc1nc(-c2cc(-c3cccnc3)cc(-c3cccnc3)c2)cc(-c2cc(-c3cccnc3)cc(-c3cccnc3)c2)n1 ; Cc1nc(-c2cc(-c3ccccn3)cc(-c3ccccn3)c2)cc(-c2cc(-c3ccccn3)cc(-c3ccccn3)c2)n1 ; O=S(=O)(c1cc(-c2ccccc2)cc(-c2ccccc2)c1)c1cc(-c2ccccc2)cc(-c2ccccc2)c1 ; c1cncc(-c2cc(-c3cccnc3)cc(-c3cc(-c4cc(-c5cccnc5)cc(-c5cccnc5)c4)ncn3)c2)c1]

For example, the composition of the functional light-emitting layer is selected from any one of the following combinations:
a first combination with composition of a host material represented by H1 and a guest material represented by D1;
a second combination with composition of a host material represented by H2 and a guest material represented by D1;
a third combination with composition of a host material represented by H3 and a guest material represented by D2;
a fourth combination with composition of a host material represented by H4 and a guest material represented by D2;
a fifth combination with composition of a host material represented by H5 and a guest material represented by Db 2;
a sixth combination with composition of a host material represented by H6 and a guest material represented by D1;
a seventh combination with composition of a host material represented by H7 and a guest material represented by D1;
an eighth combination with composition of a host material formed by mixing compounds represented by H8 and H9, and a guest material represented by D1;
a ninth combination with composition of a host material formed by mixing compounds represented by H8 and H10, and a guest material represented by D2; and
a tenth combination with composition of a host material formed by mixing compounds represented by H8 and H11, and a guest material represented by D3; and
in the functional light-emitting layer, the mass percentage content of the host material is 85-99%.

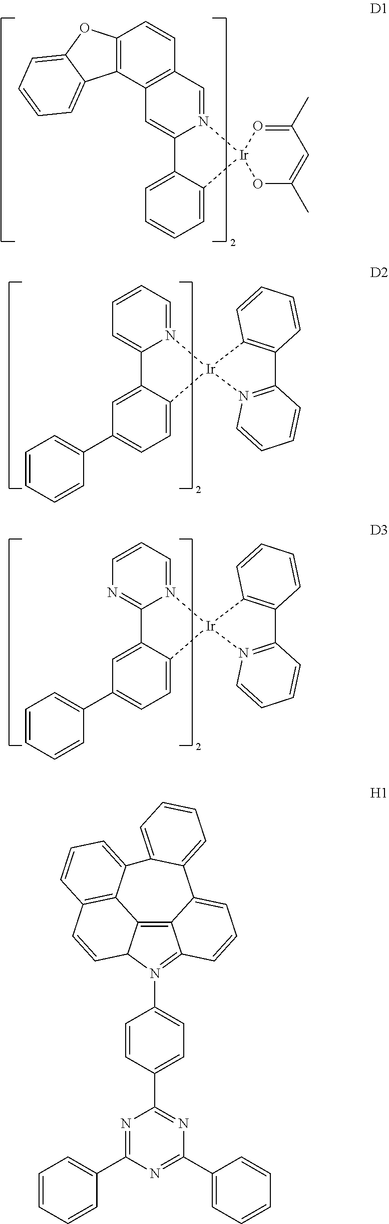

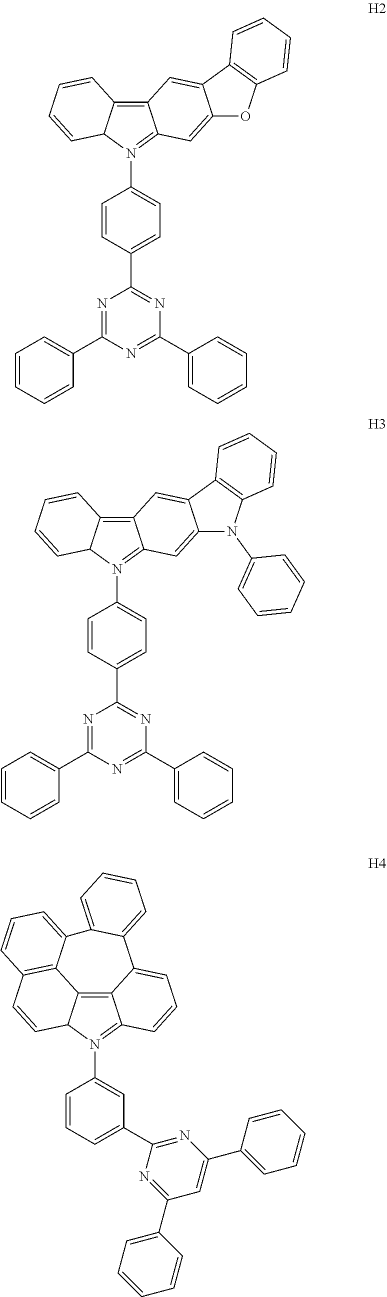

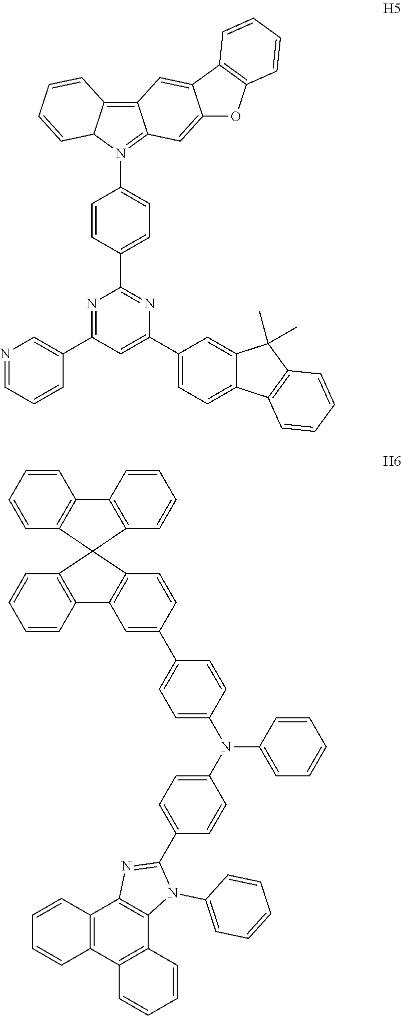

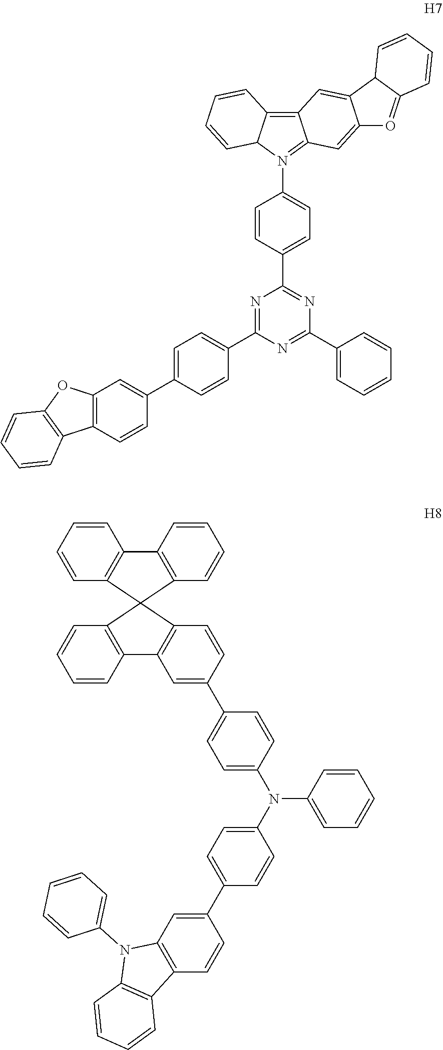

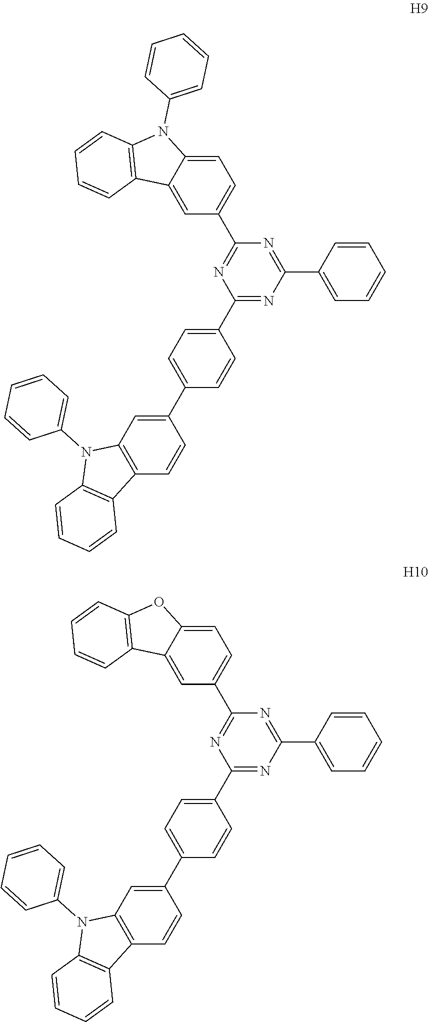 [SMILES: c1ccc(-c2nc(-c3ccc(-c4ccc5c6ccccc6n(-c6ccccc6)c5c4)cc3)nc(-c3ccc4c(c3)c3ccccc3n4-c3ccccc3)n2)cc1 ; c1ccc(-c2nc(-c3ccc(-c4ccc5c6ccccc6n(-c6ccccc6)c5c4)cc3)nc(-c3ccc4oc5ccccc5c4c3)n2)cc1]

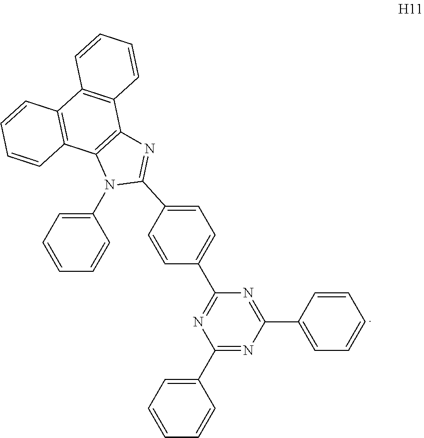 [SMILES: c1ccc(-c2nc(-c3ccccc3)nc(-c3ccc(-c4nc5c6ccccc6c6ccccc6c5n4-c4ccccc4)cc3)n2)cc1]

It can be understood that the organic electroluminescent device of the present application comprises, in addition to the functional light-emitting layer, a blue light-emitting layer, which is also provided between the cathode and the anode and is arranged in parallel with the functional light-emitting layer according to a target luminous color. In the present application, the combinations of the functional light-emitting layer and the blue light-emitting layer are collectively referred to as light-emitting layers.

In order to ensure the normal generation and transport of holes and electrons, in the organic electroluminescent device of the present application, a hole region is further provided between the anode and the light-emitting layers, and an electron region is further provided between the cathode and the light-emitting layers.

The hole region may be a hole transport layer (HTL) of a single-layer structure, including a single-layer hole transport layer containing only one compound, and a single-layer hole transport layer containing a plurality of compounds. The hole region may also be a multilayer structure sequentially comprising at least two of a hole injection layer (HIL), a hole transport layer (HTL), and an electron blocking layer (EBL) in the direction from the anode towards the light-emitting layer.

In the present application, the choices of the materials (including HIL, HTL and EBL) of the hole region are not limited, and any material commonly used in the art can be used. For example, the material may be selected from, but is not limited to, a phthalocyanine derivative such as CuPc, a conductive polymer or a conductive-dopant-containing polymer such as Polystyrene, polyaniline/dodecylbenzenesulfonic acid (Pani/DBSA), poly(3,4-ethylenedioxythiophene)/poly(4-styrenesulfonate) (PEDOT/PSS), polyaniline/camphorsulfonic acid (Pani/CSA), and polyaniline/poly(4-styrenesulfonate) (Pani/PSS), and an aromatic amine derivative.

The electron region may be an electron transport layer (ETL) of a single-layer structure, including a single-layer electron transport layer containing only one compound, and a single-layer electron transport layer containing a plurality of compounds. The electron region may also be a multilayer structure sequentially comprising at least two of an electron injection layer (EIL), an electron transport layer (ETL), and a hole blocking layer (HBL) in the direction from the cathode towards the light-emitting layer.

In the present application, the choices of the materials (including EIL, ETL and HBL) of the electron region are not limited, and any material commonly used in the art may be used. For example, the materials of the electron transport layer and the hole blocking layer may be selected from, but are not limited to, one of or a combination of two or more of ET-1 to ET-57 listed below.

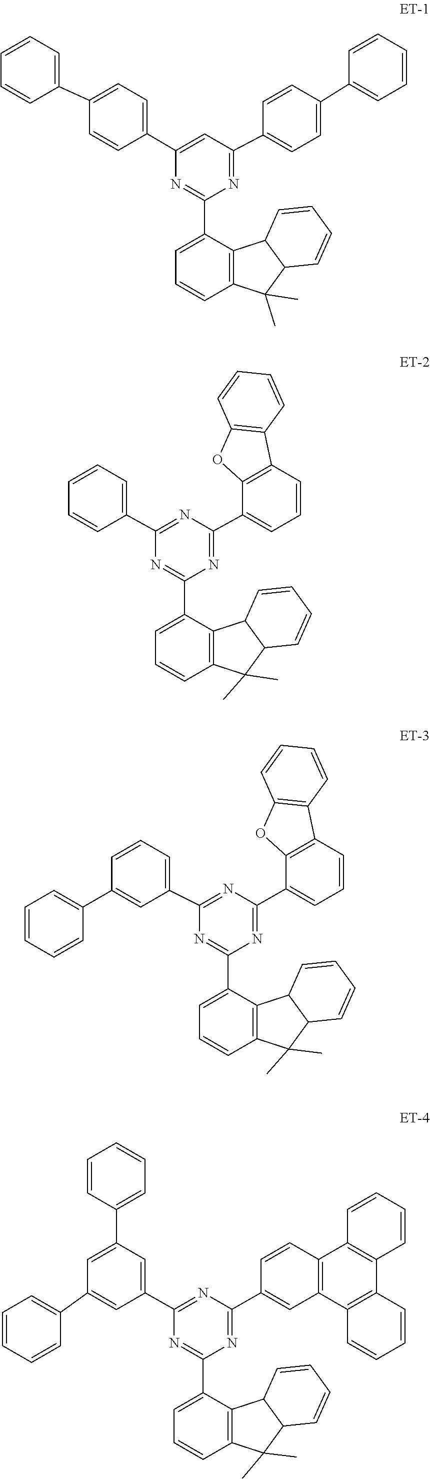 [SMILES: CC1(C)c2cccc(-c3nc(-c4ccc(-c5ccccc5)cc4)cc(-c4ccc(-c5ccccc5)cc4)n3)c2C2C=CC=CC21 ; CC1(C)c2cccc(-c3nc(-c4ccccc4)nc(-c4cccc5c4oc4ccccc45)n3)c2C2C=CC=CC21 ; CC1(C)c2cccc(-c3nc(-c4cccc(-c5ccccc5)c4)nc(-c4cccc5c4oc4ccccc45)n3)c2C2C=CC=CC21 ; CC1(C)c2cccc(-c3nc(-c4cc(-c5ccccc5)cc(-c5ccccc5)c4)nc(-c4ccc5c6ccccc6c6ccccc6c5c4)n3)c2C2C=CC=CC21]

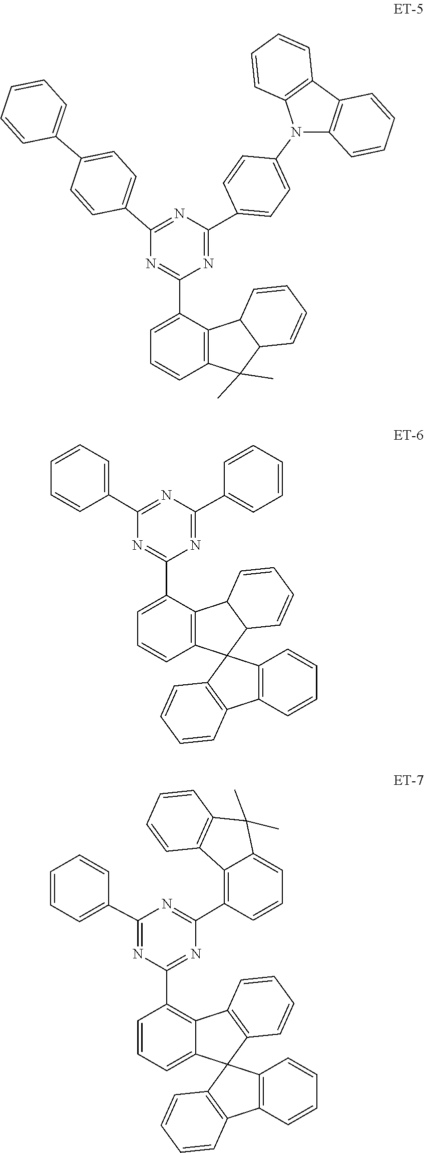 [SMILES: CC1(C)c2cccc(-c3nc(-c4ccc(-c5ccccc5)cc4)nc(-c4ccc(-n5c6ccccc6c6ccccc65)cc4)n3)c2C2C=CC=CC21 ; C1=CC2c3c(-c4nc(-c5ccccc5)nc(-c5ccccc5)n4)cccc3C3(c4ccccc4-c4ccccc43)C2C=C1 ; CC1(C)c2ccccc2-c2c(-c3nc(-c4ccccc4)nc(-c4cccc5c4-c4ccccc4C54c5ccccc5-c5ccccc54)n3)cccc21]

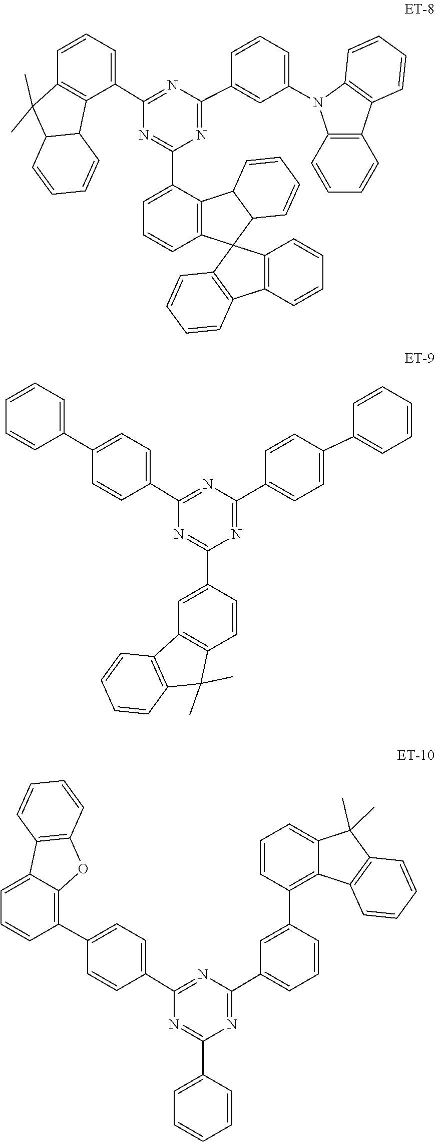 [SMILES: CC1(C)c2cccc(-c3nc(-c4cccc(-n5c6ccccc6c6ccccc65)c4)nc(-c4cccc5c4C4C=CC=CC4C54c5ccccc5-c5ccccc54)n3)c2C2C=CC=CC21 ; CC1(C)c2ccccc2-c2cc(-c3nc(-c4ccc(-c5ccccc5)cc4)nc(-c4ccc(-c5ccccc5)cc4)n3)ccc21 ; CC1(C)c2ccccc2-c2c(-c3cccc(-c4nc(-c5ccccc5)nc(-c5ccc(-c6cccc7c6oc6ccccc67)cc5)n4)c3)cccc21]

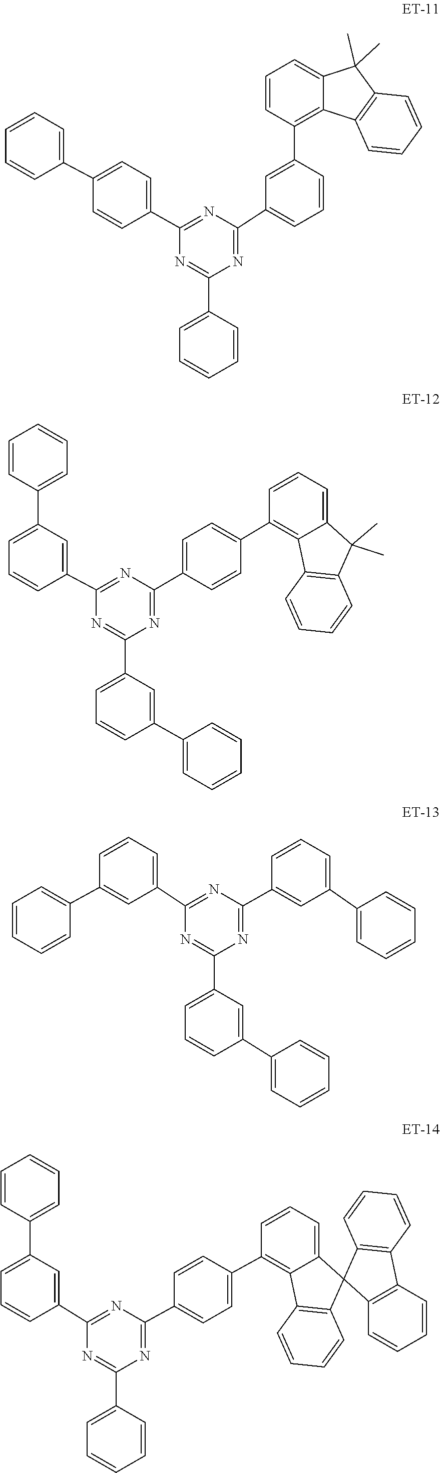 [SMILES: CC1(C)c2ccccc2-c2c(-c3cccc(-c4nc(-c5ccccc5)nc(-c5ccc(-c6ccccc6)cc5)n4)c3)cccc21 ; CC1(C)c2ccccc2-c2c(-c3ccc(-c4nc(-c5cccc(-c6ccccc6)c5)nc(-c5cccc(-c6ccccc6)c5)n4)cc3)cccc21 ; c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4ccccc4)nc(-c4ccc(-c5cccc6c5-c5ccccc5C65c6ccccc6-c6ccccc65)cc4)n3)c2)cc1]

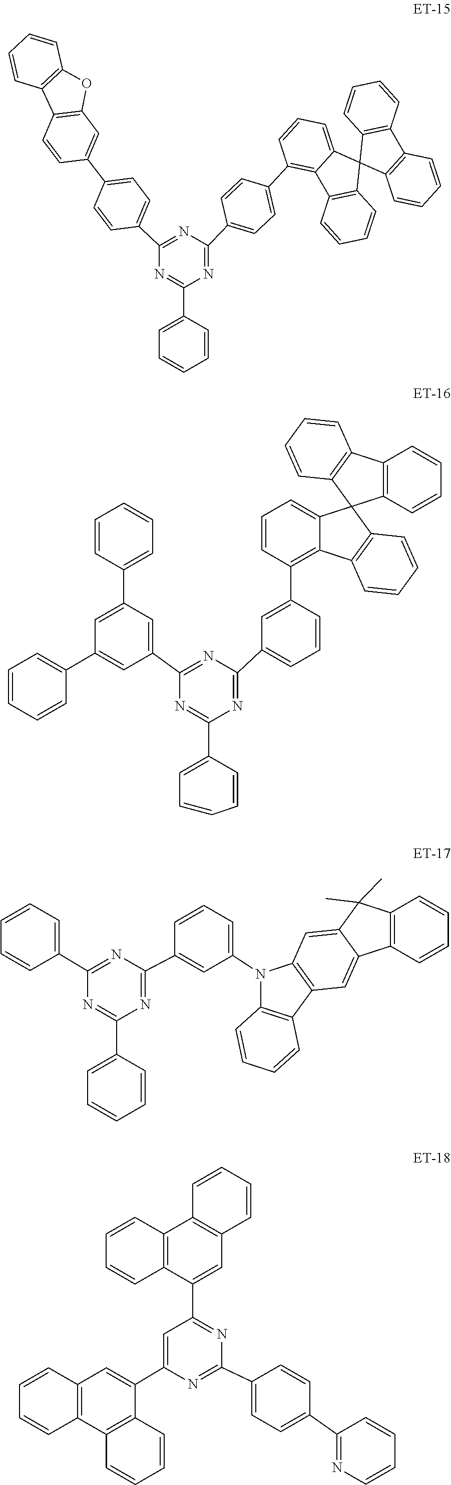 [SMILES: c1ccc(-c2nc(-c3ccc(-c4ccc5c(c4)oc4ccccc45)cc3)nc(-c3ccc(-c4cccc5c4-c4ccccc4C54c5ccccc5-c5ccccc54)cc3)n2)cc1 ; c1ccc(-c2cc(-c3ccccc3)cc(-c3nc(-c4ccccc4)nc(-c4cccc(-c5cccc6c5-c5ccccc5C65c6ccccc6-c6ccccc65)c4)n3)c2)cc1 ; CC1(C)c2ccccc2-c2cc3c4ccccc4n(-c4cccc(-c5nc(-c6ccccc6)nc(-c6ccccc6)n5)c4)c3cc21 ; c1ccc(-c2ccc(-c3nc(-c4cc5ccccc5c5ccccc45)cc(-c4cc5ccccc5c5ccccc45)n3)cc2)nc1]

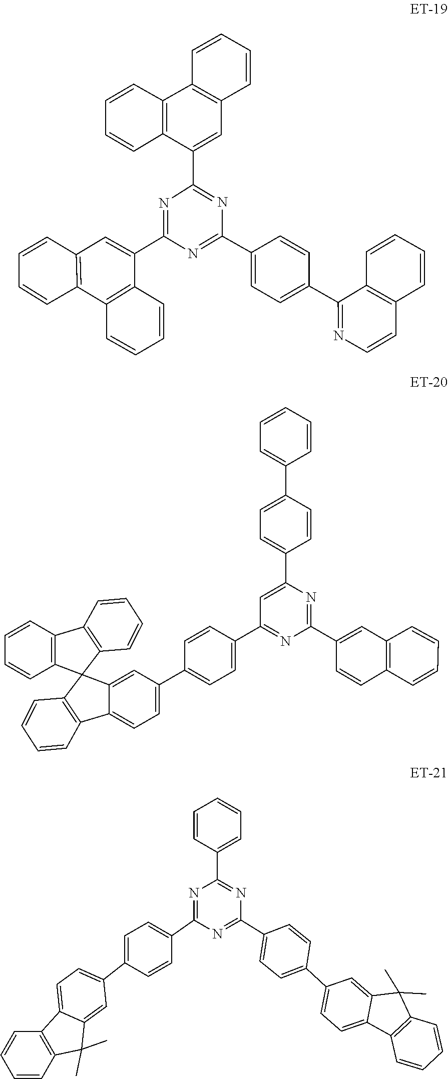 [SMILES: c1ccc2c(-c3ccc(-c4nc(-c5cc6ccccc6c6ccccc56)nc(-c5cc6ccccc6c6ccccc56)n4)cc3)nccc2c1 ; c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

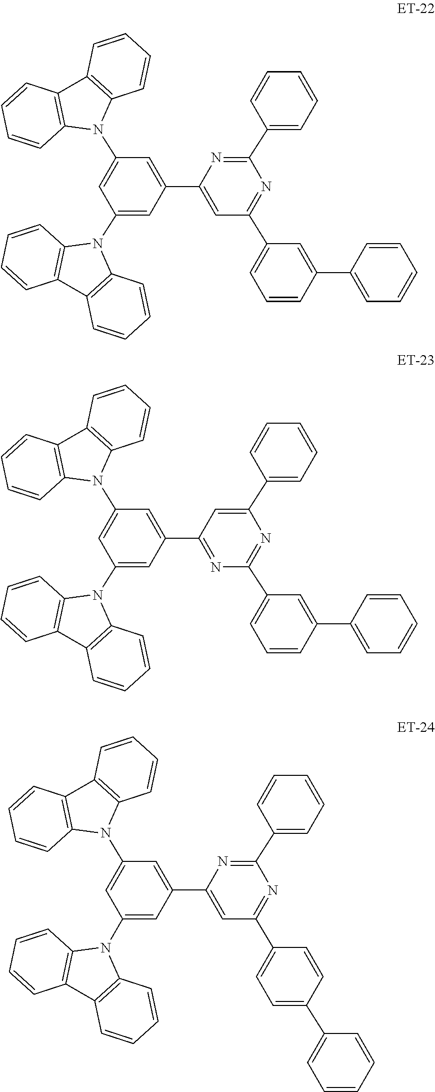

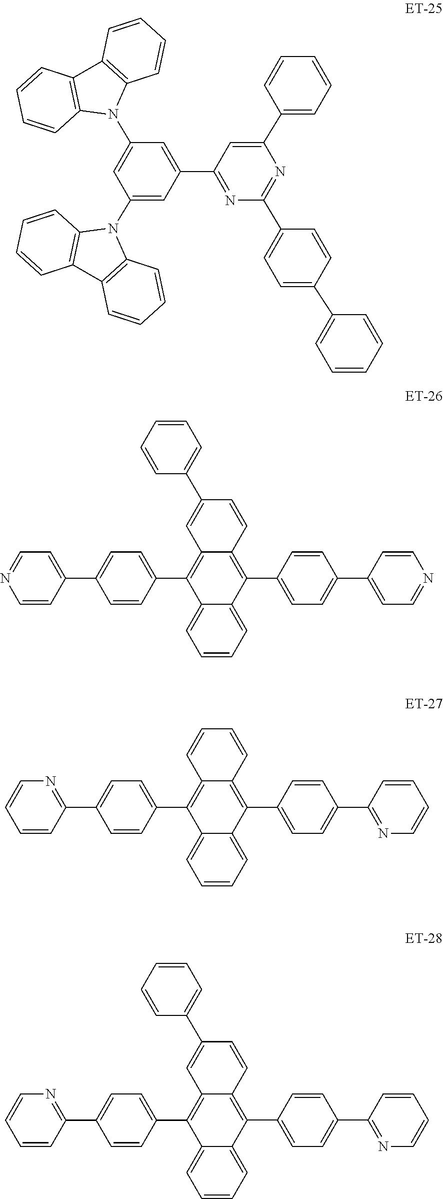 [SMILES: c1ccc(-c2ccc(-c3nc(-c4ccccc4)cc(-c4cc(-n5c6ccccc6c6ccccc65)cc(-n5c6ccccc6c6ccccc65)c4)n3)cc2)cc1 ; c1ccc(-c2ccc3c(-c4ccc(-c5ccncc5)cc4)c4ccccc4c(-c4ccc(-c5ccncc5)cc4)c3c2)cc1 ; c1ccc(-c2ccc(-c3c4ccccc4c(-c4ccc(-c5ccccn5)cc4)c4ccccc34)cc2)nc1 ; c1ccc(-c2ccc3c(-c4ccc(-c5ccccn5)cc4)c4ccccc4c(-c4ccc(-c5ccccn5)cc4)c3c2)cc1]

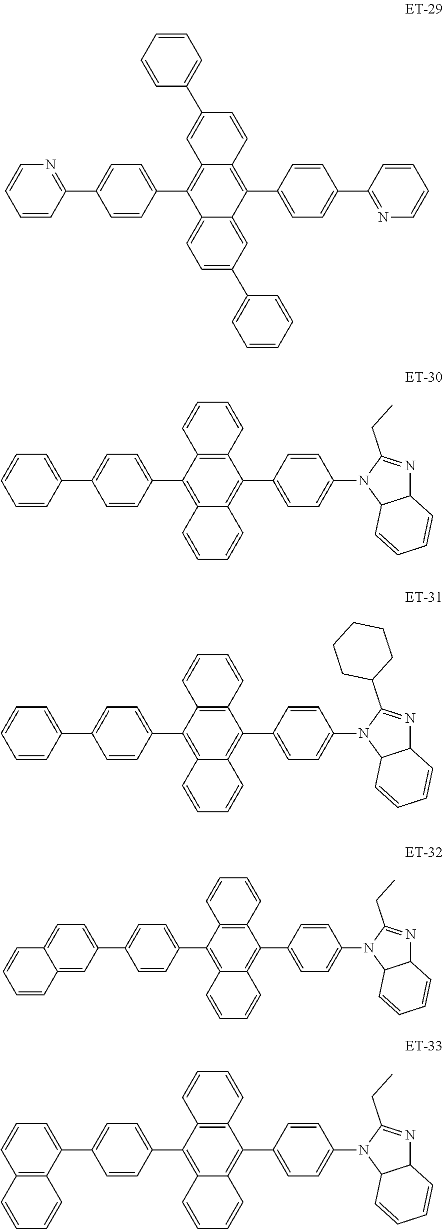

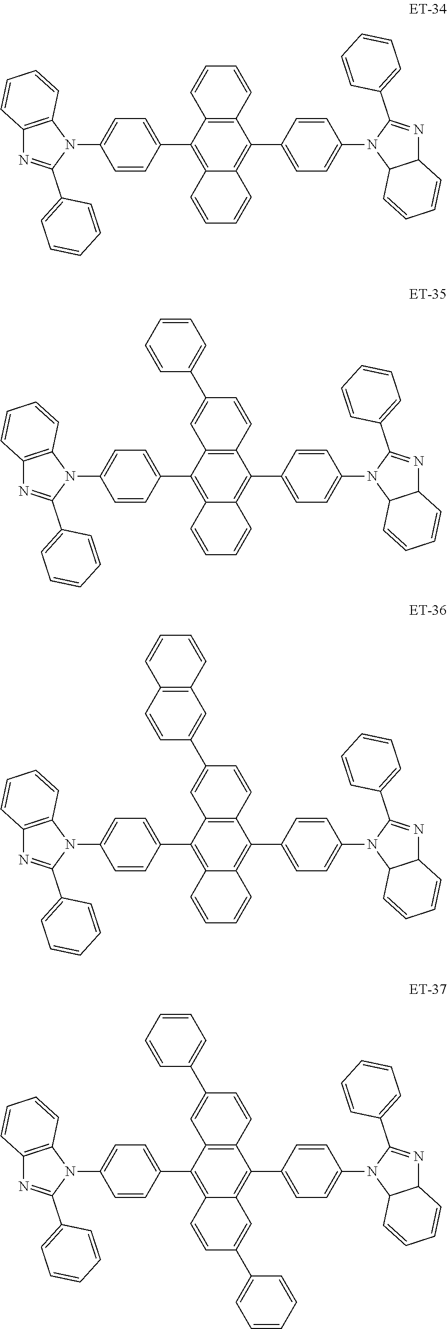 [SMILES: C1=CC2N=C(c3ccccc3)N(c3ccc(-c4c5ccccc5c(-c5ccc(-n6c(-c7ccccc7)nc7ccccc76)cc5)c5ccccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccccc6)ccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccc7ccccc7c6)ccc45)cc3)C2C=C1 ; C1=CC2N=C(c3ccccc3)N(c3ccc(-c4c5ccc(-c6ccccc6)cc5c(-c5ccc(-n6c(-c7ccccc7)nc7ccccc76)cc5)c5ccc(-c6ccccc6)cc45)cc3)C2C=C1]

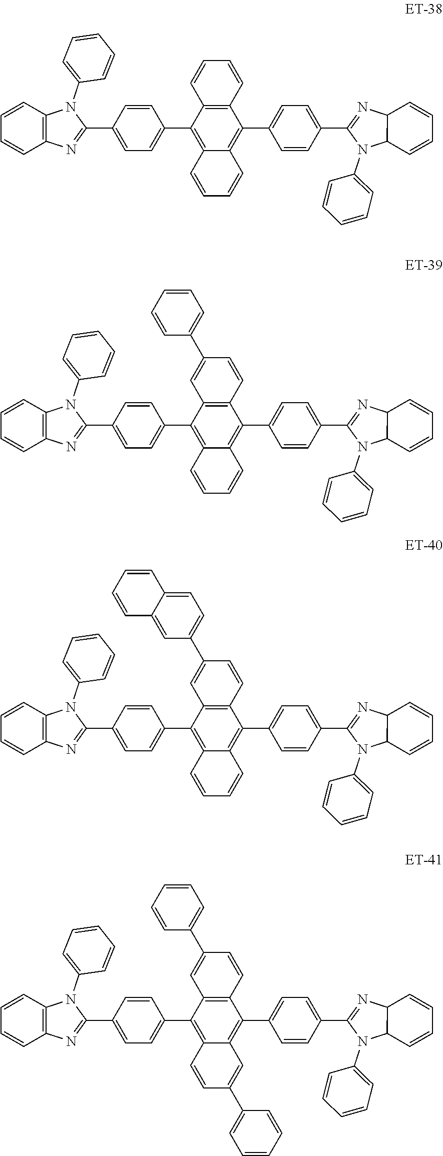 [SMILES: C1=CC2N=C(c3ccc(-c4c5ccccc5c(-c5ccc(-c6nc7ccccc7n6-c6ccccc6)cc5)c5ccccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccccc6)ccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccc7ccccc7c6)ccc45)cc3)N(c3ccccc3)C2C=C1 ; C1=CC2N=C(c3ccc(-c4c5ccc(-c6ccccc6)cc5c(-c5ccc(-c6nc7ccccc7n6-c6ccccc6)cc5)c5ccc(-c6ccccc6)cc45)cc3)N(c3ccccc3)C2C=C1]

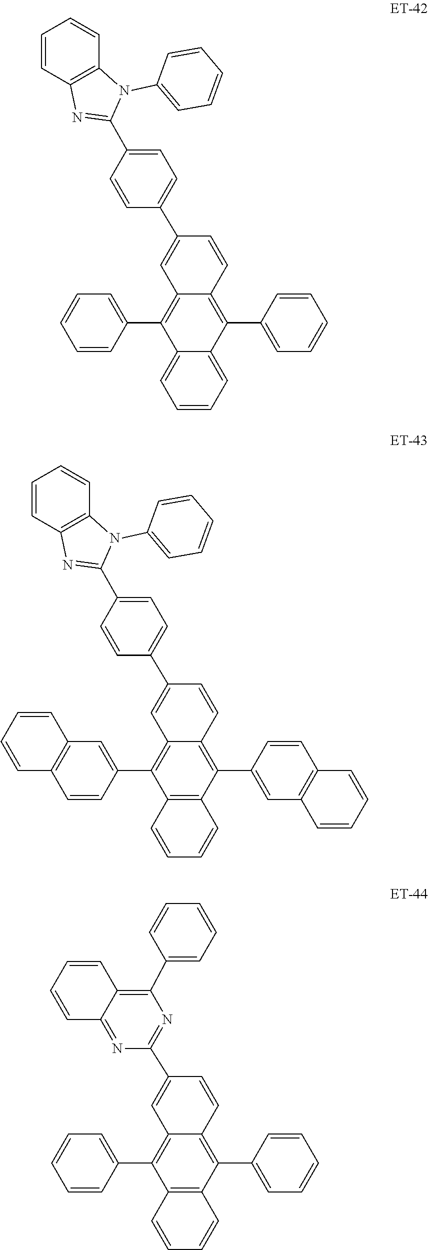

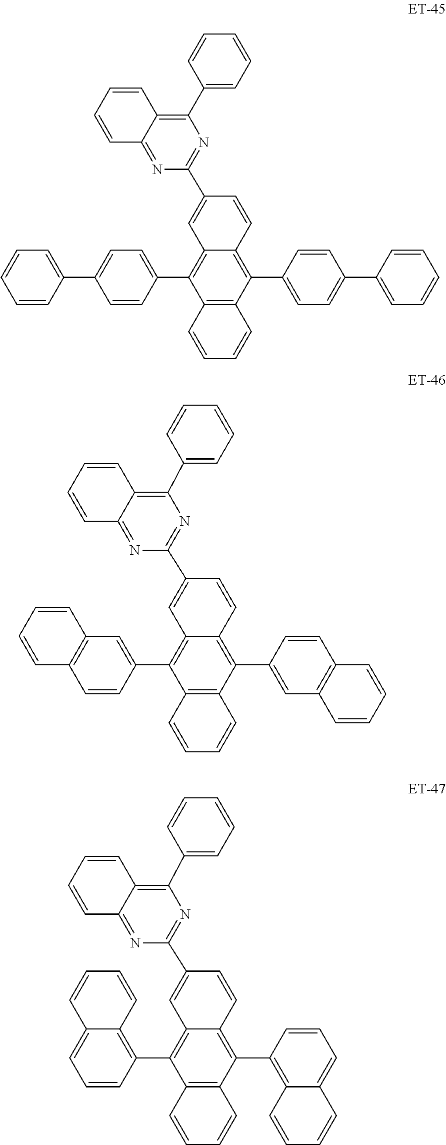

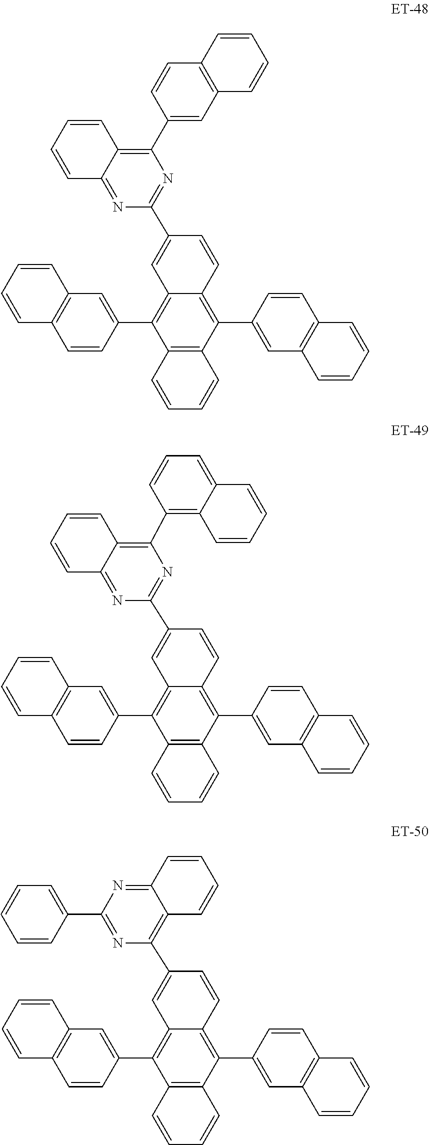 [SMILES: c1ccc2cc(-c3nc(-c4ccc5c(-c6ccc7ccccc7c6)c6ccccc6c(-c6ccc7ccccc7c6)c5c4)nc4ccccc34)ccc2c1 ; c1ccc2cc(-c3c4ccccc4c(-c4ccc5ccccc5c4)c4cc(-c5nc(-c6cccc7ccccc67)c6ccccc6n5)ccc34)ccc2c1 ; c1ccc(-c2nc(-c3ccc4c(-c5ccc6ccccc6c5)c5ccccc5c(-c5ccc6ccccc6c5)c4c3)c3ccccc3n2)cc1]

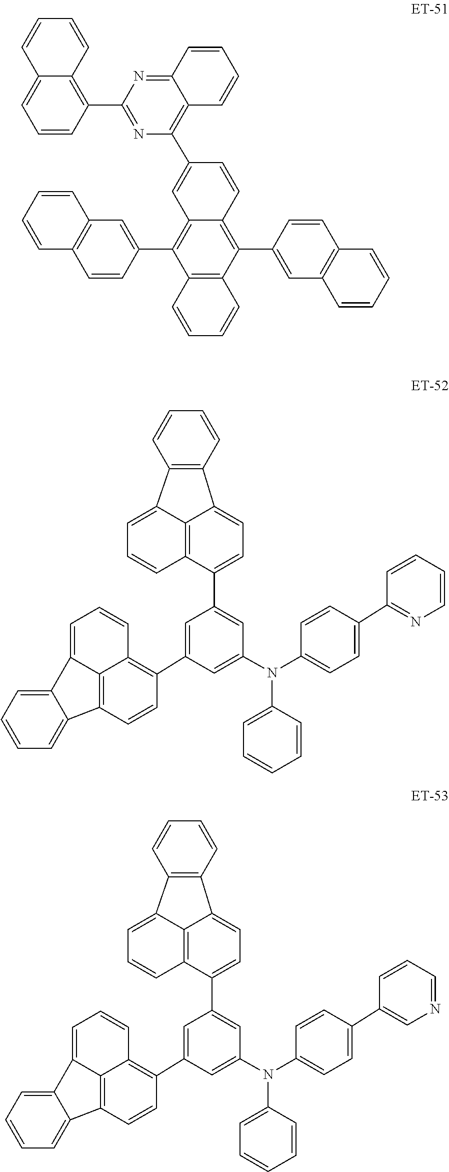 [SMILES: c1ccc2cc(-c3c4ccccc4c(-c4ccc5ccccc5c4)c4cc(-c5nc(-c6cccc7ccccc67)nc6ccccc56)ccc34)ccc2c1 ; c1ccc(N(c2ccc(-c3ccccn3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3cccnc3)cc2)c2cc(-c3ccc4c5c(cccc35)-c3ccccc3-4)cc(-c3ccc4c5c(cccc35)-c3ccccc3-4)c2)cc1]

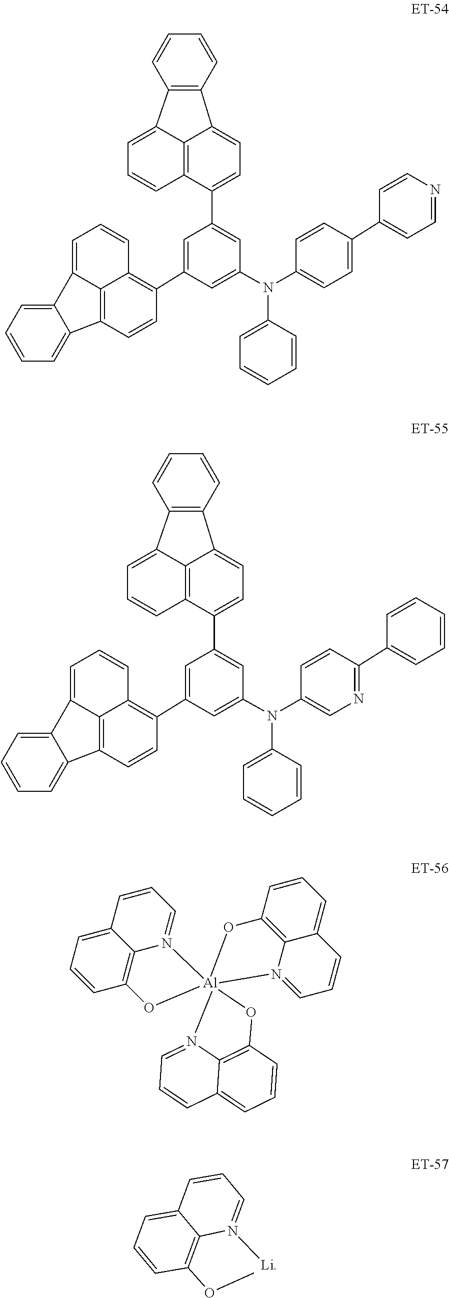

The material of the electron injection layer includes, but is not limited to, one of or a combination of two or more of the substances listed below: LiQ, LiF, NaCl, CsF, Li₂O, Cs₂CO₃, BaO, Na, Li, and Ca. Among them, LIQ is an organic semiconductor material, chemical name Lithium 8-Hydroxyquinolinolate.

The thicknesses of the layers described above may be conventional thicknesses of those layers in the art.

An example of the present application further provides a display apparatus, comprising the organic electroluminescent device as provided above. The display apparatus may specifically be a display device such as an OLED display, and any product or component comprising the display device and having a display function, such as a television, a digital camera, a mobile phone and a tablet PC. The display apparatus has the same advantages as the above organic electroluminescent device, and no more detailed description is to be given here.

The organic electroluminescent device of the present application will be further introduced in conjunction with specific examples below.

### EXAMPLES 1-10 AND COMPARATIVE EXAMPLES 1-3

Examples 1-10 and Comparative examples 1-3 provided an organic electroluminescent device, respectively. The structure of the device sequentially comprises an ITO anode, a hole injection layer (3 wt % E1+97 wt % E2, 100 Å), a hole transport layer (E2, 1200±100 Å), a light-emitting layer, an electron transport layer (50 wt % E5+50 wt % Liq, 300 Å), an electron injection layer (the material thereof being Yb, 10 Å), and a cathode (50 wt % Mg+50 wt % Ag). The light-emitting layer comprised a blue light-emitting layer (97 wt % E3+3 wt % E4, 200 Å), a green light-emitting layer (see Table 1 for the composition thereof, 400 Å), and a red light-emitting layer (see Table 1 for the composition thereof, 400 Å), which were arranged in parallel. It should be noted that 3 wt % E1+97 wt % E2 represented that the hole injection layer comprised 3 wt % of E1 and 97 wt % of E2, with a thickness of 100 Å.

Herein, the composition of the organic electroluminescent devices of Examples 1, 2, 6, 7 and 8 was almost the same as that of the organic electroluminescent device of Comparative example 2 (with the composition of the green light-emitting layers thereof being the same as that in Comparative example 3), except that the host materials in the respective red light-emitting layers were different. See Table 1 for the specific composition of the red light-emitting layers.

The composition of the organic electroluminescent devices of Examples 3, 4, 5 and 9 was almost the same as that of the organic electroluminescent device of Comparative example 3 (with the composition of the red light-emitting layers thereof being the same as that in Comparative example 2), except that the host materials in the respective green light-emitting layers were different. See Table 1 for the specific composition of the green light-emitting layers.

The composition of the organic electroluminescent device of Example 10 was almost the same as that of the organic electroluminescent device of Comparative example 1 (with the composition of the red light-emitting layer thereof being the same as that in Comparative example 2), except that the host materials in the respective green light-emitting layers were different. See Table 1 for the specific composition of the green light-emitting layers.

It should be noted that, based on the composition described above, the organic electroluminescent devices of Comparative examples 2 and 3 were actually the same. In Table 1, Comparative example 2 refers to the composition of the red light-emitting layer of the organic electroluminescent device, and Comparative example 3 refers to the composition of the green light-emitting layer of the organic electroluminescent device. In addition, Examples 1, 2, 6, 7 and 8 in Table 1 actually corresponded to the red light-emitting layers in the corresponding organic electroluminescent devices, and Examples 3, 4, 5 and 9 and Comparative example 1 in Table 1 actually corresponded to the green light-emitting layers in the corresponding organic electroluminescent devices.

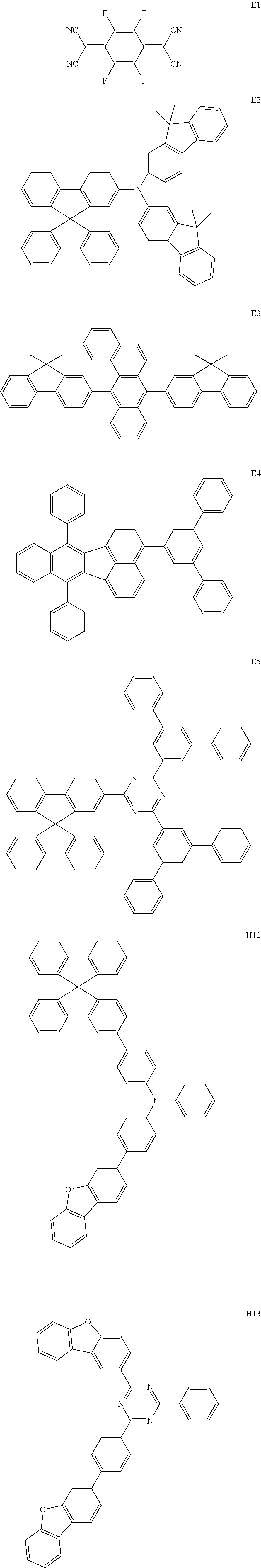

The hole mobility and the electron mobility of the red light-emitting layers R or the green light-emitting layers G in the above examples and comparative examples were obtained by testing a hole migration device (an HOD) and an electron migration device (an EOD), followed by calculation according to Formula A. See Table 1 for the specific results. The structure of the HOD and EOD was as shown below.

HOD: Anode (100 Å)/HatCN (10 Å)/NPB (1000 Å)/EML (400 Å)/NPB(300 Å)/HatCN (10 Å)/Cathode (130 Å)

EOD: Anode (100 Å)/Yb (10 Å)/TmPyPB: Liq (600 Å)/EML (400 Å)/TmPyPB: Liq (280 Å)/Yb (10 Å)/Cathode (130 Å)

TABLE 1

| | Composition of | | | | | | |
|---|---|---|---|---|---|---|---|
| | functional light- | | | | | | |
| | emitting layer | \|VE-VH \| at different current densities | | | | | |
| | Host material + | 0.01 | 0.1 | 1 | 10 | 17 | 30 |
| | dye | mA/cm² | | | | | |
| Example | 97 wt % H1 + 3 | 2.1*10⁻⁸ | 1.3*10⁻⁸ | 0.5*10⁻⁸ | 1.2*10⁻⁶ | 2.4*10⁻⁶ | 5*10⁻⁶ |
| 1 | wt % D1 | | | | | | |
| Example | 97 wt % H2 + 3 | 1.5*10⁻⁸ | 0.7*10⁻⁸ | 0.03*10⁻⁸ | 3*10⁻⁸ | 1.4*10⁻⁷ | 5.0*10⁻⁷ |
| 2 | wt % D1 | | | | | | |
| Example | 88 wt % H3 + 12 | 3.2*10⁻⁸ | 2.0*10⁻⁸ | 1.3*10⁻⁸ | 0.08*10⁻⁸ | 7.1*10⁻⁸ | 8.0*10⁻⁷ |
| 3 | wt % D2 | | | | | | |
| Example | 88 wt % H4 + 12 | 2.5*10⁻⁸ | 1.6*10⁻⁸ | 0.9*10⁻⁸ | 1.5*10⁻⁶ | 3.0*10⁻⁶ | 6.2*10⁻⁶ |
| 4 | wt % D2 | | | | | | |
| Example | 88 wt % H5 + 12 | 1.8*10⁻⁸ | 1.1*10⁻⁸ | 0.2*10⁻⁸ | 2.1*10⁻⁸ | 1.0*10⁻⁷ | 3.8*10⁻⁶ |
| 5 | wt % D2 | | | | | | |
| Example | 97 wt % H6 + 3 | 2.3*10⁻⁸ | 1.6*10⁻⁸ | 0.8*10⁻⁸ | 0.2*10⁻⁸ | 0.8*10⁻⁸ | 3.5*10⁻⁸ |
| 6 | wt % D1 | | | | | | |
| Example | 97.5 wt % H7 + | 1.1*10⁻⁸ | 0.2*10⁻⁸ | 0.5*10⁻⁸ | 1.4*10⁻⁶ | 3.3*10⁻⁶ | 6.2*10⁻⁶ |
| 7 | 2.5 wt % D1 | | | | | | |
| Example | 98 wt % Host + 2 | 1.6*10⁻⁸ | 0.8*10⁻⁸ | 0.02*10⁻⁸ | 0.9*10-7 | 2.3*10⁻⁶ | 4.7*10⁻⁶ |
| 8 | wt % D1 | | | | | | |
| | Host: | | | | | | |
| | 40 wt % H8 + 60 | | | | | | |
| | wt % H9 | | | | | | |
| Example | 91 wt % Host + 9 | 1.4*10⁻⁸ | 0.8*10⁻⁸ | 0.3*10⁻⁸ | 1.0*10⁻⁷ | 2.4*10⁻⁷ | 5.2*10⁻⁶ |
| 9 | wt % D2 | | | | | | |
| | Host: | | | | | | |
| | 50 wt % H8 + 50 | | | | | | |
| | wt % H10 | | | | | | |
| Example | 90 wt % Host + | 2.0*10⁻⁸ | 1.2*10⁻⁸ | 0.6*10⁻⁸ | 0.4*10⁻⁷ | 1.0*10⁻⁷ | 3.9*10⁻⁷ |
| 10 | 10 wt % D3 | | | | | | |
| | Host: | | | | | | |
| | 50 wt % H8 + 50 | | | | | | |
| | wt % H11 | | | | | | |
| Compar- | 90 wt % Host + | 0.5*10⁻⁸ | 0.2*10⁻⁸ | 0.03*10⁻⁸ | 5*10⁻⁸ | 2.1*10⁻⁷ | 5.3*10⁻⁶ |
| ative | 10 wt % D3 | | | | | | |
| example | Host: | | | | | | |
| 1 | 50 wt % H12 + 50 | | | | | | |
| | wt % H10 | | | | | | |
| Compar- | 97 wt % Host + 3 | 0.2*10⁻⁸ | 0.5*10⁻⁸ | 2.3*10⁻⁸ | 3.5*10⁻⁶ | 8.2*10⁻⁶ | 2.1*10⁻⁵ |
| ative | wt % D1 | | | | | | |
| example | Host: | | | | | | |
| 2 | 50 wt % H6 + 50 | | | | | | |
| | wt % H10 | | | | | | |
| Compar- | 88 wt % Host + | 0.3*10⁻⁸ | 0.1*10⁻⁸ | 0.6*10⁻⁸ | 1.2*10⁻⁷ | 2.5*10⁻⁷ | 6.2*10⁻⁶ |
| ative | 12 wt % D2 | | | | | | |
| example | Host: | | | | | | |
| 3 | 50 wt % H12 + 50 | | | | | | |
| | wt % H13 | | | | | | |

### Test Example 1

The luminous efficiency of the organic electroluminescent devices of the examples and comparative examples was tested by using a Keithley 2602 electrical test apparatus. The results are shown in Table 2.

TABLE 2

| | Luminous efficiency | | | | | |
|---|---|---|---|---|---|---|
| | 0.01 mA/cm² | 0.1 mA/cm² | 1 mA/cm² | 10 mA/cm² | 17 mA/cm² | 30 mA/cm² |
| Example | 49 cd/A | 50 cd/A | 51 cd/A | 49 cd/A | 46 cd/A | 44 cd/A |
| 1 | | | | | | |
| Example | 50 cd/A | 51 cd/A | 51 cd/A | 50 cd/A | 47 cd/A | 45 cd/A |
| 2 | | | | | | |
| Example | 162 cd/A | 170 cd/A | 182 cd/A | 184 cd/A | 180 cd/A | 170 cd/A |
| 3 | | | | | | |
| Example | 171 cd/A | 178 cd/A | 182 cd/A | 176 cd/A | 173 cd/A | 165 cd/A |
| 4 | | | | | | |
| Example | 174 cd/A | 180 cd/A | 183 cd/A | 180 cd/A | 176 cd/A | 168 cd/A |
| 5 | | | | | | |
| Example | 47 cd/A | 49 cd/A | 51 cd/A | 51 cd/A | 49 cd/A | 46 cd/A |
| 6 | | | | | | |
| Example | 51 cd/A | 53 cd/A | 52 cd/A | 49 cd/A | 46 cd/A | 44 cd/A |
| 7 | | | | | | |
| Example | 50 cd/A | 51 cd/A | 52 cd/A | 50 cd/A | 46 cd/A | 44 cd/A |
| 8 | | | | | | |
| Example | 175 cd/A | 181 cd/A | 183 cd/A | 178 cd/A | 175 cd/A | 166 cd/A |
| 9 | | | | | | |
| Example | 186 cd/A | 195 cd/A | 198 cd/A | 182 cd/A | 177 cd/A | 170 cd/A |
| 10 | | | | | | |
| Compar- | 194 cd/A | 198 cd/A | 193 cd/A | 175 cd/A | 170 cd/A | 166 cd/A |
| ative | | | | | | |
| example | | | | | | |
| 1 | | | | | | |
| Compar- | 53 cd/A | 55 cd/A | 54 cd/A | 49 cd/A | 46 cd/A | 43 cd/A |
| ative | | | | | | |
| example | | | | | | |
| 2 | | | | | | |
| Compar- | 192 cd/A | 190 cd/A | 186 cd/A | 168 cd/A | 164 cd/A | 152 cd/A |
| ative | | | | | | |
| example | | | | | | |
| 3 | | | | | | |

As can be seen from Table 2:
1. Compared to Comparative example 3, the composition of the green light-emitting layers of Examples 3, 4, 5 and 9 of the present application is advantageous for the organic electroluminescent devices to have reduced luminous efficiency of green light under a low gray scale, thereby suppressing the deterioration of the display quality caused by crosstalk from green light; in addition, under a high gray scale, the luminous efficiency of green light in Examples 3, 4, 5 and 9 is better than or equivalent to that in Comparative example 3. Therefore, the organic electroluminescent devices based on Examples 3, 4, 5 and 9 of the present application have better display quality and luminous efficiency.

Similarly, compared to Comparative example 1, the composition of the green light-emitting layer of Example 10 of the present application is advantageous for the organic electroluminescent device to have reduced luminous efficiency of green light under a low gray scale, thereby suppressing the deterioration of display quality caused by crosstalk from green light; in addition, under a high gray scale, the luminous efficiency of green light in Example 10 is better than or equivalent to that in Comparative example 1. Therefore, the organic electroluminescent device based on Example 10 of the present application has better display quality and luminous efficiency.
2. Compared to Comparative example 2, the composition of the red light-emitting layers of Examples 1, 2, 6, 7 and 8 of the present application is advantageous for the organic electroluminescent devices to have reduced luminous efficiency of red light under a low gray scale, thereby suppressing the deterioration of the display quality caused by crosstalk from red light; in addition, under a high gray scale, the luminous efficiency of red light in Examples 1, 2, 6, 7 and 8 is better than or equivalent to that of Comparative example 2. Therefore, the organic electroluminescent devices based on Examples 1, 2, 6, 7 and 8 of the present application have better display quality and luminous efficiency.

### Test Example 2

The organic electroluminescent devices of Comparative example 2, Example 1 and Example 9 were subjected to photoluminescence spectroscopic detection under a low gray scale of G4 with the spectroscopic test apparatus CS200.

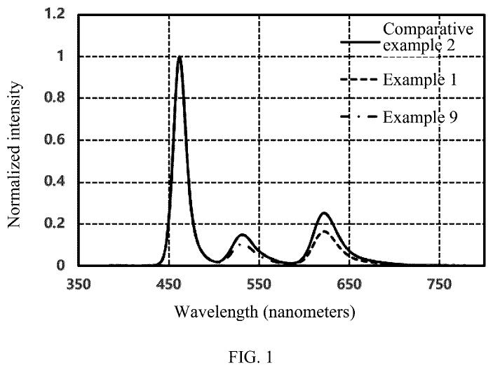

FIG. 1 shows the photoluminescence spectra of the organic electroluminescent devices of Example 1, Example 9, and Comparative example 2 of the present application.

As can be seen from FIG. 1, as compared to Comparative example 2, the crosstalk from red light in the organic electroluminescent device of Example 1 is significantly suppressed, and the crosstalk from green light in the organic electroluminescent device of Example 9 is significantly suppressed. Therefore, the functional light-emitting layer with low luminous efficiency under a low gray scale in the present application is beneficial for the organic electroluminescent device to have reduced crosstalk from red and green light, thus improving the display quality of the organic electroluminescent device.

Finally, it should be noted that the examples above are merely used to elaborate, not limit, the embodiments of the present application. Although the present application has been described in detail with reference to the examples described above, it should be understood in the art that the embodiments described in the foregoing examples may still be modified, or part or all of the features thereof may be equivalently substituted; however, these modifications or substitutions do not cause the essence of the corresponding embodiment to deviate from the scopes of the embodiments in the examples of the present application.

1. An organic electroluminescent device, comprising at least one functional light-emitting layer,
wherein in a first target current density interval not greater than 0.01 mA/cm², an electron mobility V_{E} and a hole mobility V_{H} of the at least one functional light-emitting layer satisfy the requirements of Formula 1:
$$\vert {V}_{E} - {V}_{H} \vert > 1 * {10}^{- 8} {cm}^{2} / V s . \qquad Formula 1$$

2. The organic electroluminescent device according to claim 1, wherein the functional light-emitting layer is a red light-emitting layer or a green light-emitting layer.

3. The organic electroluminescent device according to claim 1, wherein the at least one functional light-emitting layer comprises a plurality of functional light-emitting layers, the functional light-emitting layers comprise a red light-emitting layer and a green light-emitting layer.

4. The organic electroluminescent device according to claim 1, wherein in the first target current density interval, the electron mobility V_{E} and the hole mobility V_{H} of the functional light-emitting layer satisfy the requirements of Formula 2:
$$\vert {V}_{E} - {V}_{H} \vert > {{2}^{}}^{*} {10}^{- 8} {cm}^{2} / V s . \qquad Formula 2$$

5. The organic electroluminescent device according to claim 1, wherein in a target current subinterval of greater than 0.01 mA/cm² and less than or equal to 5 mA/cm², the electron mobility V_{E} and the hole mobility V_{H} of the functional layer satisfy the requirements of Formula 3:
$$\vert {V}_{E} - {V}_{H} \vert ⩽ 1 * {10}^{- 8} {cm}^{2} / V s . \qquad Formula 3$$

6. The organic electroluminescent device according to claim 1, wherein in a target current subinterval of greater than 5 mA/cm², the electron mobility V_{E} and the hole mobility V_{H} of the functional layer satisfy the requirements of Formula 4:
$$\vert {V}_{E} - {V}_{H} \vert ⩽ 3.5 * {10}^{- 6} {cm}^{2} / V s . \qquad Formula 4$$

7. The organic electroluminescent device according to claim 5, wherein in a target current subinterval of greater than 5 mA/cm², the electron mobility V_{E} and the hole mobility V_{H} of the functional layer satisfy the requirements of Formula 4:
$$\vert {V}_{E} - {V}_{H} \vert ⩽ 3.5 * {10}^{- 6} {cm}^{2} / V s . \qquad Formula 4$$

8. The organic electroluminescent device according to claim 1, wherein in a second target current density interval of greater than 0.01 mA/cm² and less than or equal to 10 mA/cm², the electron mobility V_{E1} and the hole mobility V_{H1} of the functional light-emitting layer at a first current density and the electron mobility V_{E2} and the hole mobility V_{H2} of the functional light-emitting layer at a second current density satisfy the requirements of Formula 5:
$$0 < \vert {V}_{E 2} < {V}_{H 2} \vert < \vert {V}_{E 1} - {V}_{H 1} \vert \qquad Formula 5$$
wherein the first current density is less than the second current density.

9. The organic electroluminescent device according to claim 5, wherein in a second target current density interval of greater than 0.01 mA/cm² and less than or equal to 10 mA/cm², the electron mobility V_{E1} and the hole mobility V_{H1} of the functional light-emitting layer at a first current density and the electron mobility V_{E2} and the hole mobility V_{H2} of the functional light-emitting layer at a second current density satisfy the requirements of Formula 5:
$$0 < \vert {V}_{E 2} < {V}_{H 2} \vert < \vert {V}_{E 1} - {V}_{H 1} \vert \qquad Formula 5$$
wherein the first current density is less than the second current density.

10. The organic electroluminescent device according to claim 1, wherein in a second target current density interval of greater than 0.01 mA/cm² and less than or equal to 10 mA/cm², the electron mobility V_{E3} and the hole mobility V_{H3} of the functional light-emitting layer at a third current density satisfy the requirements of Formula 6:
$$\vert {V}_{E 3} - {V}_{H 3} \vert = 0. \qquad Formula 6$$

11. The organic electroluminescent device according to claim 1, wherein the functional light-emitting layer comprises a host material and a guest material;
wherein the host material comprises a bipolar material, or the host material comprises at least one of a mixture of an electron-donor material and an electron-acceptor material, a mixture of the bipolar material and the electron-donor material, and a mixture of the bipolar material and the electron-acceptor material; and
the guest material is a phosphorescent dye or a fluorescent dye.

12. The organic electroluminescent device according to claim 11, wherein the host material comprises the mixture of the bipolar material and the electron-donor material, and the mass ratio of the bipolar material to the electron-donor material is (1-9):(9-1).

13. The organic electroluminescent device according to claim 12, wherein the mass ratio of the bipolar material to the electron-donor material is _{(3-7):(7-3}).

14. The organic electroluminescent device according to claim 13, wherein the mass ratio of the bipolar material to the electron-donor material is (_{4-6):(6-4}).

15. The organic electroluminescent device according to claim 14, wherein the mass ratio of the bipolar material to the electron-donor material is 1:1.

16. The organic electroluminescent device according to claim 11, wherein the electron-donor material is a compound containing at least one electron-donating group selected from carbazolyl, arylamino, silyl, fluorenyl, dibenzothienyl, and dibenzofuranylaryl.

17. The organic electroluminescent device according to claim 11, wherein the electron-acceptor material is a compound containing at least one electron-accepting group selected from pyridyl, pyrimidinyl, triazinyl, imidazolyl, o-phenanthrolinyl, sulfonyl, heptazinyl, oxadiazolyl, cyano and diphenylphosphoryl.

18. The organic electroluminescent device according to claim 1, wherein the functional light-emitting layer comprises a host material and a guest material; the host material comprises at least one of the following materials: 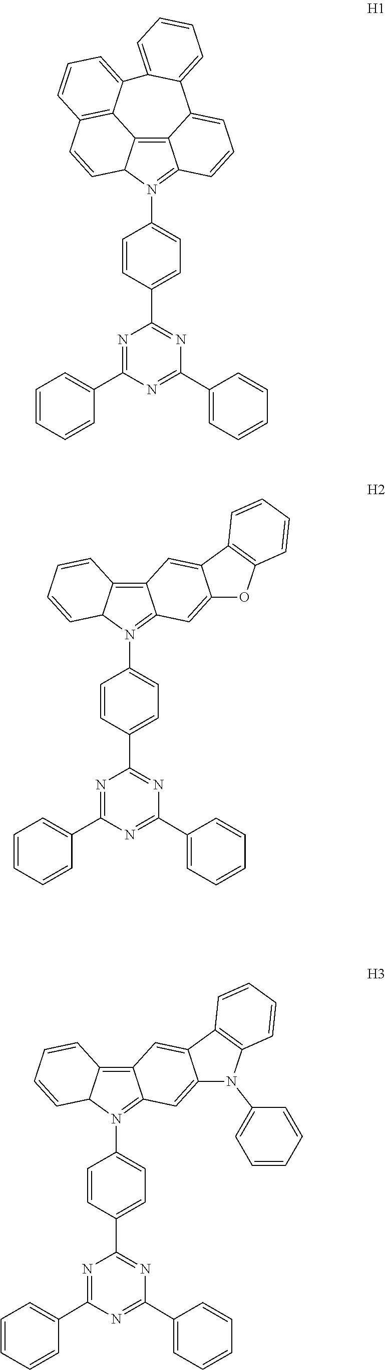 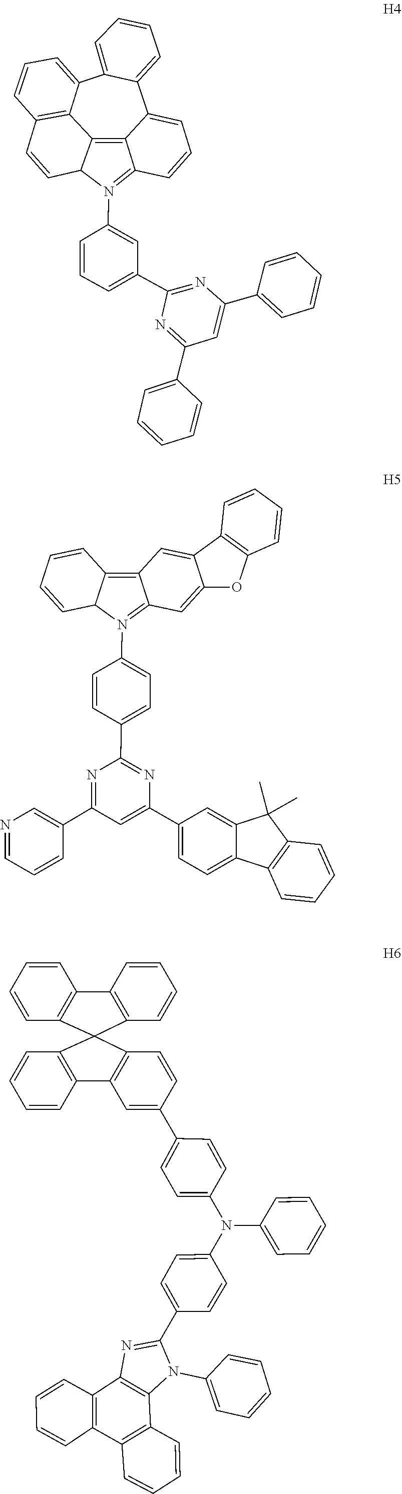 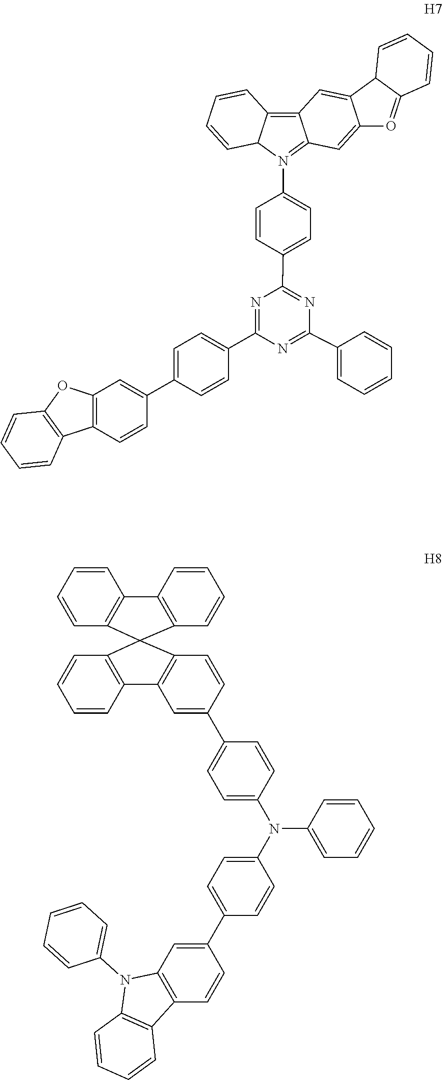 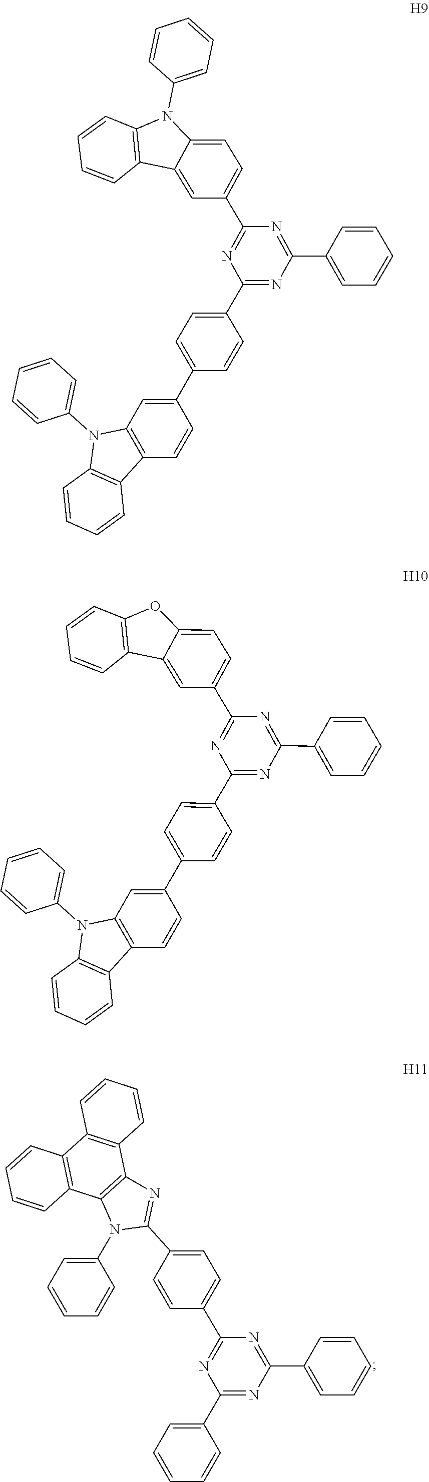 [SMILES: c1ccc(-c2nc(-c3ccc(-c4ccc5c6ccccc6n(-c6ccccc6)c5c4)cc3)nc(-c3ccc4c(c3)c3ccccc3n4-c3ccccc3)n2)cc1 ; c1ccc(-c2nc(-c3ccc(-c4ccc5c6ccccc6n(-c6ccccc6)c5c4)cc3)nc(-c3ccc4oc5ccccc5c4c3)n2)cc1 ; c1ccc(-c2nc(-c3ccccc3)nc(-c3ccc(-c4nc5c6ccccc6c6ccccc6c5n4-c4ccccc4)cc3)n2)cc1]
and the guest material comprises at least one of the following materials:

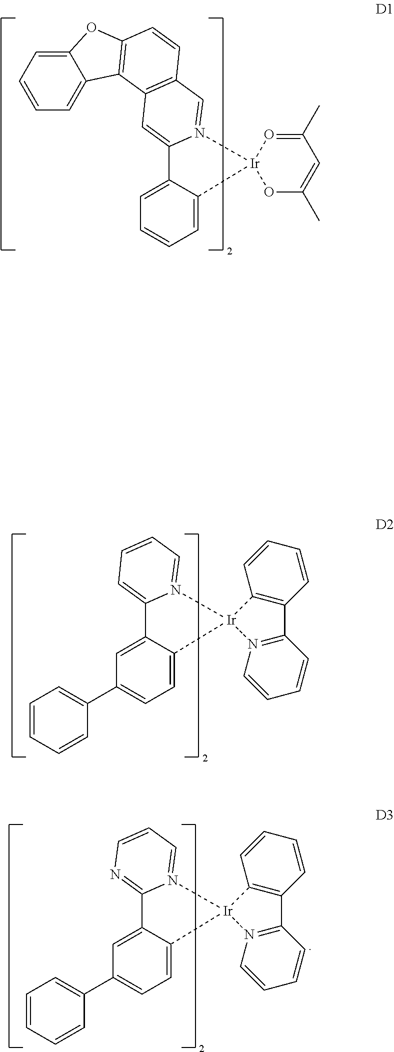

19. The organic electroluminescent device according to claim 16, wherein the composition of the functional light-emitting layer is selected from any one of the following combinations:
a first combination with composition of a host material represented by H1 and a guest material represented by D1;
a second combination with composition of a host material represented by H2 and a guest material represented by D1;
a third combination with composition of a host material represented by H3 and a guest material represented by D2;
a fourth combination with composition of a host material represented by H4 and a guest material represented by D2;
a fifth combination with composition of a host material represented by H5 and a guest material represented by D2;
a sixth combination with composition of a host material represented by H6 and a guest material represented by D1;
a seventh combination with composition of a host material represented by H7 and a guest material represented by D1;
an eighth combination with composition of a host material formed by mixing compounds represented by H8 and H9, and a guest material represented by D1;
a ninth combination with composition of a host material formed by mixing compounds represented by H8 and H10, and a guest material represented by D2; and
a tenth combination with composition of a host material formed by mixing compounds represented by H8 and H11, and a guest material represented by D3,
wherein in the functional light-emitting layer, the mass percentage content of the host material is 85-99%.

20. A display apparatus, comprising the organic electroluminescent device according to claim 1.
